(19) United States
(12) Patent Application Publication
(10) Pub. No.: US 2026/0301651 A1
(43) Pub. Date: Oct. 1, 2026

(54) DISPLAY PANEL AND DISPLAY APPARATUS

(71) Applicant: Wuhan Tianma Microelectronics Co., Ltd., Wuhan (CN)

(72) Inventor: Wenshuai ZHANG, Wuhan (CN)

(73) Assignee: Wuhan Tianma Microelectronics Co., Ltd., Wuhan (CN)

(21) Appl. No.: 19/414,247

(22) Filed: Dec. 9, 2025

(30) Foreign Application Priority Data
Apr. 1, 2025 (CN) 202510405001.2

(51) Int. Cl. G09G 3/32

(52) U.S. Cl. CPC G09G 3/32; G09G 2310/0245; G09G 2310/0267; G09G 2310/0286; G09G 2330/021

(57) ABSTRACT

A display panel and a display apparatus are disclosed in the present application. The display panel includes a first driving circuit, the first driving circuit includes a plurality of stages of shift registers. The shift register includes a shift control module and a shift output module that are configured to control the first node, the second node, and the shift output terminal, and to control the shift output terminal to output a shift signal; a first control module is configured to control a signal of the fourth node; a second control module is configured to adjust the signal of the fourth node; and a refresh output module is configured to control the scan output terminal to output a gate driving signal.

### CROSS-REFERENCE TO RELATED APPLICATIONS

This application claims priority to Chinese Patent Application No. 202510405001.2, titled “DISPLAY PANEL AND DISPLAY APPARATUS” and filed on Apr. 1, 2025, which is hereby incorporated by reference in its entirety.

### TECHNICAL FIELD

The present application relates to the field of display technology, and particularly to a display panel and a display apparatus.

### BACKGROUND

With the rapid development of display technology, display screens based on multi-zone dynamic refresh technology have emerged. Display screens using multi-zone dynamic refresh technology can perform different refresh rates in the dynamic picture area and static picture area of the display area, or can present different refresh rates in the human eye observation area and non-human eye observation area of the display area, thereby realizing partitioned display control of the display area. In this way, both refresh rate requirements and low power consumption requirements can be taken into account.

However, the current display screens with partitioned refresh function have problems such as poor stability, which affects the display effect.

### SUMMARY

The present application provides a display panel and a display apparatus to solve the problems such as poor stability that the current display screens with partitioned refresh function have.

According to an aspect of the present application, a display panel is provided, which includes a first driving circuit, the first driving circuit includes a plurality of stages of shift registers, each of the shift registers comprises: a shift control module electrically connected to an input terminal, a first clock terminal, a second clock terminal, a first power supply terminal, a second power supply terminal, a first node and a second node for controlling a signal of the first node and a signal of the second node; a shift output module electrically connected to the first node, the second node, the first power supply terminal, the second power supply terminal and a shift output terminal for controlling the shift output terminal to output a shift signal; a first control module electrically connected to the first node, a third node and a fourth node for controlling a signal of the fourth node, the third node is configured to receive a first refresh control signal provided by a first refresh signal line; a second control module electrically connected to the third node and the fourth node for adjusting the signal of the fourth node, the second control module is further electrically connected to the first node, or the first control module is electrically connected to the fourth node through the second control module; and a refresh output module electrically connected to the second node, the fourth node, a third power supply terminal, a fourth power supply terminal, and a scan output terminal for controlling the scan output terminal to output a gate driving signal.

According to another aspect of the present application, a display apparatus is provided, which includes the display panel as described above.

It should be understood that the contents described in this part are not intended to identify the key or important features of the embodiments of the present application, nor are they intended to limit the scope of the present application. Other features of the present application will become easily understood through the following specification.

### BRIEF DESCRIPTION OF THE DRAWINGS

In order to more clearly explain the technical solutions in the embodiments of the present application, the drawings that need to be used in the description of the embodiments will be briefly introduced below, apparently, the drawings described below are only some embodiments of the present application, for those skilled in the art, other drawings can be obtained based on these drawings without creative work.

FIG. 1 is a schematic diagram of a display panel according to an embodiment of the present application.

FIG. 2 is a schematic diagram of a first driving circuit according to an embodiment of the present application.

FIG. 3 is a schematic diagram of a shift register according to an embodiment of the present application.

FIG. 4 is a schematic diagram of a shift register according to another embodiment of the present application;

FIG. 5 is a schematic diagram of a shift register according to yet another embodiment of the present application;

FIG. 6 is a schematic diagram of a shift output portion according to an embodiment of the present application.

FIG. 7 is a schematic diagram of a shift output portion according to another embodiment of the present application.

FIG. 8 is a schematic diagram of a shift register according to still yet another embodiment of the present application.

FIG. 9 is a low-frequency operation timing diagram of a shift register in a first display partition shown in FIG. 8.

FIG. 10 is a high-frequency operation timing diagram of a shift register in a second display partition shown in FIG. 8.

FIG. 11 is a schematic diagram of a shift register according to even still yet another embodiment of the present application.

FIG. 12 is a schematic diagram of a shift register according to even still yet another embodiment of the present application.

FIG. 13 is a schematic diagram of a shift register according to even still yet another embodiment of the present application.

FIG. 14 is a schematic diagram of a shift register according to even still yet another embodiment of the present application.

FIG. 15 is a schematic diagram of a shift register according to even still yet another embodiment of the present application.

FIG. 16 is a schematic diagram of a shift register according to even still yet another embodiment of the present application.

FIG. 17 is a schematic diagram of a shift register according to even still yet another embodiment of the present application.

FIG. 18 is a schematic diagram of a shift register according to even still yet another embodiment of the present application.

FIG. 19 is a schematic diagram of a shift register according to even still yet another embodiment of the present application.

FIG. 20 is a schematic diagram of a shift register according to even still yet another embodiment of the present application.

FIG. 21 is a schematic diagram of a shift register according to even still yet another embodiment of the present application.

FIG. 22 is a low-frequency operation timing diagram of a shift register in a first display partition shown in FIG. 21.

FIG. 23 is a high-frequency operation timing diagram of a shift register in a second display partition shown in FIG. 21.

FIG. 24 is a schematic structural diagram of a display apparatus according to an embodiment of the present application.

### DETAILED DESCRIPTION

In order to enable those skilled in the art to better understand the solutions of the present application, the technical solutions in the embodiments of the present application will be clearly and completely described below with reference to the drawings in the embodiments of the present application, apparently, the described embodiments are only some embodiments of the present application, rather than all embodiments. Based on the embodiments in the present application, all other embodiments obtained by those skilled in the art without creative work should belong to the scope of protection of the present application.

It should be noted that the terms "first", "second", and the like in the specification and claims of the present application and the drawings are used to distinguish similar objects, and are not necessarily used to describe a specific order or sequence. It should be understood that the data so used may be interchangeable where appropriate so that the embodiments of the present application described herein can be implemented in an order other than those illustrated or described herein. Furthermore, the terms "comprising" and "having" and any variations thereof are intended to cover a non-exclusive inclusion, for example, a process, method, system, product, or device comprising a series of steps or units is not necessarily limited to those steps or units clearly listed, but may include other steps or units not clearly listed or inherent to such processes, methods, products, or devices.

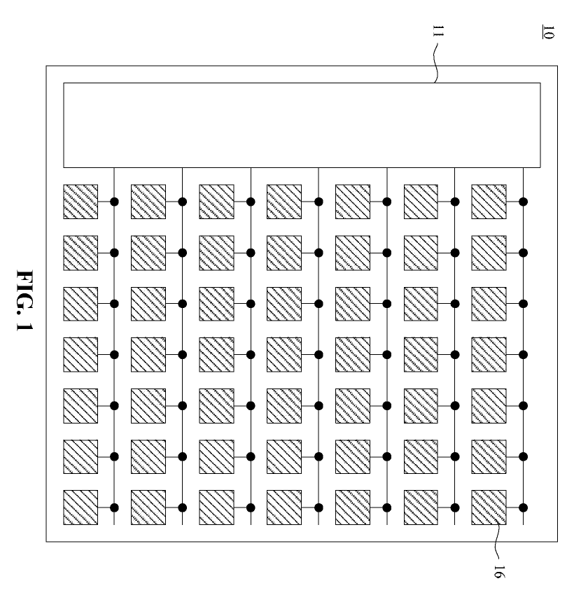

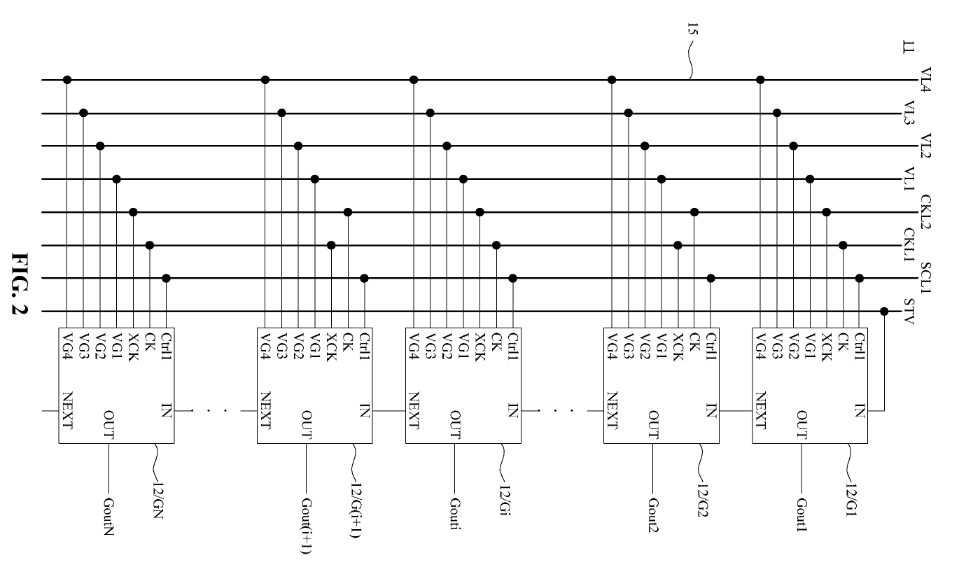

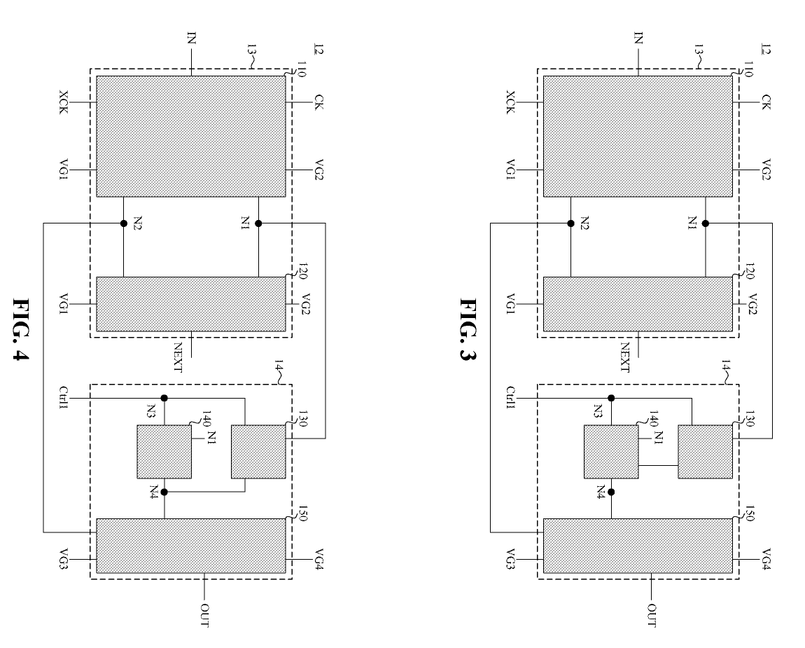

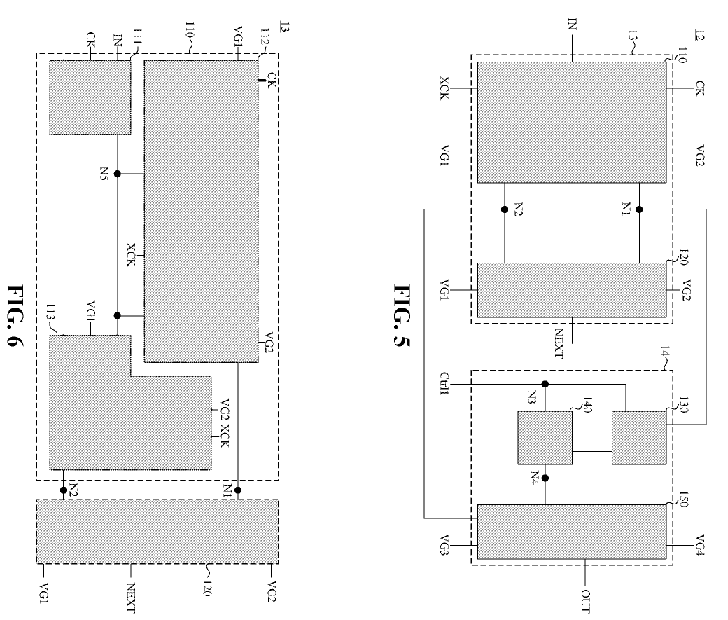

FIG. 1 is a schematic diagram of a display panel according to an embodiment of the present application, FIG. 2 is a schematic diagram of a first driving circuit according to an embodiment of the present application, FIG. 3 is a schematic diagram of a shift register according to an embodiment of the present application, FIG. 4 is a schematic diagram of a shift register according to another embodiment of the present application, and FIG. 5 is a schematic diagram of a shift register according to yet another embodiment of the present application. Referring to FIGS. 1 to 5, the display panel 10 includes: a first driving circuit 11 including a plurality of stages of shift registers 12. The shift register 12 includes: a shift control module 110 electrically connected to an input terminal IN, a first clock terminal CK, a second clock terminal XCK, a first power supply terminal VG1, a second power supply terminal VG2, a first node N1, and a second node N2 and configured to control a signal of the first node N1 and a signal of the second node N2; a shift output module 120 electrically connected to the first node N1, the second node N2, the first power supply terminal VG1, the second power supply terminal VG2, and the shift output terminal NEXT and configured to control the shift output terminal NEXT to output a shift signal; a first control module 130 electrically connected to the first node N1, the third node N3, and the fourth node N4 and configured to control a signal of the fourth node N4; wherein the third node N3 is configured to receive the first refresh control signal Ctrl1 provided from the first refresh signal line SCL1; a second control module 140 electrically connected to the third node N3 and the fourth node N4 for adjusting the signal of the fourth node N4, wherein the second control module 140 is also electrically connected to the first node N1, and/or the first control module 130 is electrically connected to the fourth node N4 through the second control module 140; and a refresh output module 150 electrically connected to the second node N2, the fourth node N4, a third power supply terminal VG3, a fourth power supply terminal VG4 and a scan output terminal OUT for controlling the scan output terminal OUT to output the gate driving signal Gout.

As shown in FIG. 3, optionally, the second control module 140 is also electrically connected to the first node N1, and the first control module 130 is electrically connected to the fourth node N4 through the second control module 140. As shown in FIG. 4, optionally, second control module 140 is also electrically connected to the first node N1, and the first control module 130 is directly electrically connected to the fourth node N4. As shown in FIG. 5, optionally, first control module 130 is electrically connected to the fourth node N4 through the second control module 140.

In this embodiment, the shift control module 110 is electrically connected to the input terminal IN, the first clock terminal CK, the second clock terminal XCK, the first power supply terminal VG1, the second power supply terminal VG2, the first node N1, and the second node N2, specifically, the input terminal IN provides an input signal, the first clock terminal CK provides a first clock signal, the second clock terminal XCK provides a second clock signal, the first power supply terminal VG1 provides a first power supply signal, and the second power supply terminal VG2 provides a second power supply signal. The first clock signal is different from the second clock signal, and it is optional that the frequency of the first clock signal is the same as the frequency of the second clock signal, while the phase of the first clock signal is different from the phase of the second clock signal. The first power supply signal is different from the second power supply signal, and one of the first power supply signal and the second power supply signal is at low level and the other is at high level. The shift control module 110 controls the signal of the first node N1 and the signal of the second node N2 according to the input signal, the first clock signal, the second clock signal, the first power supply signal, and the second power supply signal.

The shift output module 120 controls the shift output terminal NEXT to output the shift signal according to the signal of the first node N1, the signal of the second node N2, the first power supply signal, and the second power supply signal. The shift signal includes an active level and an inactive level.

The first control module 130 controls the signal of the fourth node N4 according to the signal of the first node N1 and the signal of the third node N3. Here, the first refresh control signal Ctrl1 provided by the first refresh signal line SCL1 may be directly transmitted to the third node N3, that is, the signal of the third node N3 is the first refresh control signal Ctrl1 provided by the first refresh signal line SCL1. In another embodiment, optionally, a switch structure is provided between the first refresh signal line SCL1 and the third node N3, when the switch structure is turned on, the first refresh control signal Ctrl1 provided by the first refresh signal line SCL1 is transmitted to the third node N3.

Referring to FIG. 3, the second control module 140 controls the signal of the fourth node N4 according to the signal of the third node N3, the signal of the first node N1, and the signal of the first control module 130.

Referring to FIG. 4, the second control module 140 controls the signal of the fourth node N4 according to the signal of the third node N3 and the signal of the first node N1. The signal of the fourth node N4 is influenced by the first control module 130 and the second control module 140 collectively.

Referring to FIG. 5, the second control module 140 controls the signal of the fourth node N4 according to the signal of the third node N3 and the signal of the first control module 130. The signal of the fourth node N4 is influenced by the first control module 130 and the second control module 140 collectively.

The refresh output module 150 controls the scan output terminal OUT to output the gate driving signal Gout according to the signal of the second node N2, the signal of the fourth node N4, the third power supply signal provided by the third power supply terminal VG3, and the fourth power supply signal provided by the fourth power supply terminal VG4. The gate driving signal Gout includes an active level and an inactive level. The third power supply signal is different from the fourth power supply signal, and one of the third power supply signal and the fourth power supply signal is a low level and the other is a high level.

If there is no second control module 140 in the shift register 12, the fourth node N4 is directly electrically connected to the first control module 130, and the signal of the fourth node N4 is directly influenced by the first control module 130. When the fourth node N4 is at the high level and the first node N1 is at the low level, if the first control module 130 is turned off, the high level of the fourth node N4 is easily interfered by the first control module 130, and the current leakage to the first node N1 occurs. Accordingly, the potential of the fourth node N4 gradually decreases due to the current leakage, which may cause the output of the shift register 12 to fail.

In the present application, the potential of the fourth node N4 is affected not only by the first control module 130 but also by the second control module 140 by adding the second control module 140 in the shift register 12. Under the joint action of the first control module 130 and the second control module 140, the additional second control module 140 can stabilize the potential of the fourth node N4. Specifically, when the potential of the fourth node N4 is at low level, the second control module 140 controls the potential of the fourth node N4 to be maintained at low level. When the potential of the fourth node N4 is at high level, the second control module 140 controls the potential of the fourth node N4 to be maintained at high level. Particularly, when the first node N1 is at low level and the first control module 130 is turned off, the additional second control module 140 can control the potential of the fourth node N4 to be maintained at high level, which reduces the leakage current to the first node N1 caused by the interference of the first control module 130 on the high level of the fourth node N4, thereby avoiding the problem that the potential of the fourth node N4 gradually decreases due to the leakage current and the refresh output module 150 is erroneously controlled. Based on this, by adding the second control module 140 in the present application, the potential stability of the fourth node N4 of the shift register 12 and the output stability of the gate driving signal Gout can be improved, which is conducive to ensuring the output validity, accuracy, and stability of the shift register 12, and further conducive to improving the display quality of the display panel.

The above is the core idea of the present application, based on the embodiments in the present application, all other embodiments obtained by those skilled in the art without making creative work belong to the scope of protection of the present application. Hereinafter, the technical solutions in the embodiments of the present application will be clearly and completely described with reference to the drawings in the embodiments of the present application.

Optionally, as shown in FIGS. 1 to 2, the display panel 10 may further include a plurality of signal lines 15 for supplying signals to the first driving circuit 11. Exemplarily, the first refresh signal line SCL1 provides the first refresh control signal Ctrl1 to the shift register 12; a first clock signal line CKL1 and a second clock signal line CKL 2 provide a first clock signal to the first clock terminal CK of the shift register 12 and provide a second clock signal to the second clock terminal XCK of the shift register 12, respectively; the first power supply signal line VL1 provides a first power supply signal to the first power supply terminal VG1 of the shift register 12; the second power supply signal line VL2 provides a second power supply signal to the second power supply terminal VG2 of the shift register 12; the third power supply signal line VL3 provides a third power supply signal to the third power supply terminal VG3 of the shift register 12; the fourth power supply signal line VL4 provides a fourth power supply signal to the fourth power supply terminal VG4 of the shift register 12; the input signal line STV provides an input signal to the input terminal IN of at least one stage of the shift register 12; the display panel 10 may also include a plurality of other types of signal lines 15, which are not repeated here.

As can be understood, with reference to FIG. 1, the display panel 10 may include a plurality of pixels 16, and each of the pixels 16 may include a pixel circuit and a light-emitting element. The pixel circuit controls the supply of a driving current to the light-emitting element according to a gate driving signal Gout provided by the shift register 12, so as to drive the light-emitting element to emit light. The gate driving signal Gout output by the shift register 12 may be configured to control the writing of data signals to the pixel circuit, or the gate driving signal Gout output by the shift register 12 may be configured to control the duration of the pixel circuit providing the driving current to the light-emitting element, or the gate driving signal Gout output from the shift register 12 may be configured to control the initialization of the pixel circuit, and the like, without limiting the function of the gate driving signal Gout output from the shift register 12. It should be noted that the structure of the pixel circuit of each pixel 16 in the display panel 10 can be designed according to actual needs, which are not specially limited in the embodiments of the present application.

Referring to FIGS. 3 to 5, in the display panel 10, the shift register 12 includes a shift control module 110 and a shift output module 120, the shift control module 110 and the shift output module 120 constitute a shift output portion 13 of the shift register 12. The shift output portion 13 includes an input terminal IN and a shift output terminal NEXT, and the shift output portion 13 is configured to control the shift output terminal NEXT to output a shift signal, the shift signal includes an active level and an inactive level. The shift register 12 further includes a first control module 130, a second control module 140, and a refresh output module 150, the first control module 130, the second control module 140, and the refresh output module 150 constitute a scan output portion 14, and the scan output portion 14 includes a scan output terminal OUT. The scan output portion 14 is also electrically connected to a first refresh signal line SCL1. The scan output portion 14 controls the scan output terminal OUT to output a gate driving signal Gout in response to the first refresh control signal Ctrl1 provided by the first refresh signal line SCL1, the gate driving signal Gout includes an active level and an inactive level.

Referring to FIG. 2, optionally, the shift output terminal NEXT of the shift register 12 at the i-th stage is electrically connected to the input terminal IN of the shift register 12 at the (i + m)-th stage, where m = 1, and then the shift signal output by the shift output portion 13 of the shift register 12 at the i-stage is transmitted to the input terminal IN of the shift register 12 at the (i+1)-th stage. In other embodiments, the shift output terminal NEXT of the shift register at the i-th stage may also be electrically connected to the input terminal IN of the shift register at the (i + m)-thstage, where m may be an integer greater than 1, such as m = 2, or m = 3, or m = 4, or m is equal to other positive integers, and is not limited to m = 1 as shown in FIG. 2.

In the display panel 10, the arrangement of the shift output portion 13 of the shift register 12 is diverse. Exemplarily, the shift output portion 13 may be "13T2C", "13T3C", "15T3C", or "16T3C", and the like, where "T" represents a transistor and "C" represents a storage capacitor. The arrangement of the shift output portion 13 is not limited thereto. In the following embodiments, the shift output portion 13 adopts "16T3C" as an example to illustrate the electrical connection relationship and the operation process of the shift registers 12, and the relevant practitioners can adaptively adjust the shift output portion 13 according to the needs, and the shift output portion 13 is not limited to "16T3C".

FIG. 6 is a schematic diagram of a shift output portion according to an embodiment of the present application. As shown in FIG. 6, optionally, in the shift output portion 13, the shift control module 110 includes: a first shift sub-module 111 electrically connected to an input terminal IN, a first clock terminal CK, and a fifth node N5 and configured to control a signal of the fifth node N5; a second shift sub-module 112 electrically connected to the fifth node N5, the first clock terminal CK, the second clock terminal XCK, the first power supply terminal VG1, the second power supply terminal VG2 and the first node N1 for controlling a signal of the first node N1; and a third shift sub-module 113 electrically connected to the fifth node N5, the second clock terminal XCK, the first power supply terminal VG1, the second power supply terminal VG2, and the second node N2 for controlling a signal of the second node N2.

In the present embodiment, the first shift sub-module 111 is electrically connected to the input terminal IN, the first clock terminal CK, and the fifth node N5 for controlling the signal of the fifth node N5. Specifically, the input terminal IN of the first shift sub-module 111 of the shift register 12 at the i-th stage is electrically connected to the shift output terminal NEXT of the shift register 12 at the (i-m)-thstage, where m is an integer greater than or equal to 1. The input terminal IN of the first shift sub-module 111 receives an input signal, and the first clock terminal CK of the first shift sub-module 111 receives a first clock signal. The first shift sub-module 111 controls the signal of the fifth node N5 in response to the input signal and the first clock signal, so that the potential of the fifth node N5 undergoes toggling between high and low levels.

The second shift sub-module 112 is electrically connected to the fifth node N5, the first clock terminal CK, the second clock terminal XCK, the first power supply terminal VG1, the second power supply terminal VG2, and the first node N1. The first clock terminal CK of the second shift sub-module 112 receives a first clock signal, and the second clock terminal XCK of the second shift sub-module 112 receives a second clock signal, the first clock signal of the first clock terminal CK is different from the second clock signal of the second clock terminal XCK. The first clock signal and the second clock signal may have the same frequency and different phases, but the present application is not limited thereto. The first power supply terminal VG1 of the second shift sub-module 112 receives a first power supply signal, and the second power supply terminal VG2 of the second shift sub-module 112 receives a second power supply signal. The first power supply signal of the first power supply terminal VG1 is different from the second power supply signal of the second power supply terminal VG2. One of the first power supply signal and the second power supply signal may be at low level, and the other may be at high level. The second shift sub-module 112 controls the signal of the first node N1 in response to the signal of the fifth node N5, the first clock signal, the second clock signal, the first power supply signal, and the second power supply signal, so that the potential of the first node N1 undergoes toggling between high and low levels.

The third shift sub-module 113 is electrically connected to the fifth node N5, the second clock terminal XCK, the first power supply terminal VG1, the second power supply terminal VG2, and the second node N2. The third shift sub-module 113 controls the signal of the second node N2 in response to the signal of the fifth node N5, the second clock signal, the first power supply signal, and the second power supply signal, so that the potential of the second node N2 undergoes toggling between high and low levels.

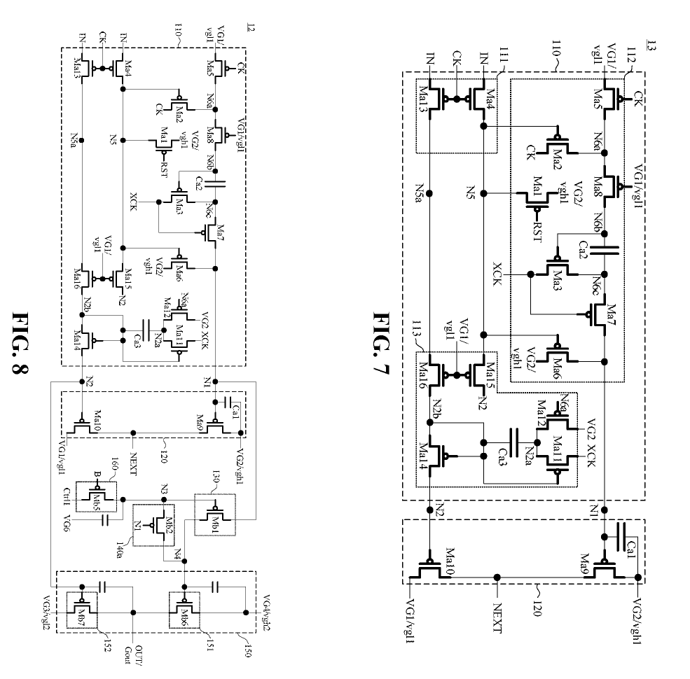

FIG. 7 is a schematic diagram of a shift output portion according to another embodiment of the present application. As shown in FIG. 7, the shift output portion 13 in FIG. 7 may be "16T3C".

Optionally, the first shift sub-module 111 includes a transistor Ma4 and a transistor Ma13. The gate of the transistor Ma4 is electrically connected to the first clock terminal CK, the first terminal of the transistor Ma4 is electrically connected to the input terminal IN, and the second terminal of the transistor Ma4 is electrically connected to the fifth node N5. The gate of the transistor Ma13 is electrically connected to the first clock terminal CK, the first terminal of the transistor Ma13 is electrically connected to the input terminal IN, and the second terminal of the transistor Ma13 is electrically connected to the node N5a. The first clock signal provided by the first clock terminal CK controls the transistor Ma4 and the transistor Ma13 to be turned on or off simultaneously. When the transistor Ma4 and the transistor Ma13 are turned on simultaneously, the input signal provided by the input terminal IN is written to the fifth node N5 and the node N5a. It can be understood that the signal of the node N5a is the same as the signal of the fifth node N5. In other embodiments, optionally, the first shift sub-module includes one of transistor Ma4 and transistor Ma13.

Optionally, the second shift sub-module 112 includes a transistor Ma1, a transistor Ma2, a transistor Ma3, a transistor Ma5, a transistor Ma6, a transistor Ma7, a transistor Ma8, and a capacitor Ca2. The gate of the transistor Ma1 is electrically connected to the reset signal terminal RST, the first terminal of the transistor Ma1 is electrically connected to the second power supply terminal VG2, and the second terminal of the transistor Ma1 is electrically connected to the fifth node N5. The gate of the transistor Ma2 is electrically connected to the fifth node N5, the first terminal of the transistor Ma2 is electrically connected to the first clock terminal CK, and the second terminal of the transistor Ma2 is electrically connected to the node N6a. The gate of the transistor Ma3 is electrically connected to the node N6b, the first terminal of the transistor Ma3 is electrically connected to the second clock terminal XCK, and the second terminal of the transistor Ma3 is electrically connected to the node N6c. The gate of the transistor Ma5 is electrically connected to the first clock terminal CK, the first terminal of the transistor Ma5 is electrically connected to the first power supply terminal VG1, and the second terminal of the transistor Ma5 is electrically connected to the node N6a. The gate of the transistor Ma6 is electrically connected to the fifth node N5, the first terminal of the transistor Ma6 is electrically connected to the second power supply terminal VG2, and the second terminal of the transistor Ma6 is electrically connected to the first node N1. The gate of the transistor Ma7 is electrically connected to the second clock terminal XCK, the first terminal of the transistor Ma7 is electrically connected to the node N6c, and the second terminal of the transistor Ma7 is electrically connected to the first node N1. The gate of the transistor Ma8 is electrically connected to the first power supply terminal VG1, the first terminal of the transistor Ma8 is electrically connected to the node N6a, and the second terminal of the transistor Ma8 is electrically connected to the node N6b. The first plate of the capacitor Ca2 is electrically connected to the node N6b, and the second plate of the capacitor Ca2 is electrically connected to the node N6c. In other embodiments, optionally, the type or number of transistors in the second shift sub-module can be adaptively adjusted, and the connection relationships of the transistors and the signal terminals change accordingly, and the structure of the second shift sub-module is not limited to that shown in FIG. 7.

Optionally, the third shift sub-module 113 includes a transistor Ma11, a transistor Ma12, a transistor Ma14, a transistor Ma15, a transistor Ma16, and a capacitor Ca3. The gate of the transistor Ma11 is electrically connected to the node N2b, the first terminal of the transistor Ma11 is electrically connected to the second clock terminal XCK, and the second terminal of the transistor Ma11 is electrically connected to the node N2a. The gate of the transistor Ma12 is electrically connected to the node N6a, the first terminal of the transistor Ma12 is electrically connected to the second power supply terminal VG2, and the second terminal of the transistor Ma12 is electrically connected to the node N2a. The gate of the transistor Ma14 is electrically connected to the node N2b, the first terminal of the transistor Ma14 is electrically connected to the node N2b, and the second terminal of the transistor Ma14 is electrically connected to the second node N2. The gate of the transistor Ma15 is electrically connected to the first power supply terminal VG1, the first terminal of the transistor Ma15 is electrically connected to the fifth node N5, and the second terminal of the transistor Ma15 is electrically connected to the second node N2. The gate of the transistor Ma16 is electrically connected to the first power supply terminal VG1, the first terminal of the transistor Ma16 is electrically connected to the fifth node N5 or node N5a, and the second terminal of the transistor Ma16 is electrically connected to the node N2b. The first plate of the capacitor Ca3 is electrically connected to the node N2a, and the second plate of the capacitor Ca3 is electrically connected to the node N2b. In other embodiments, optionally, the type or number of transistors in the third shift sub-module can be adaptively adjusted, and the connection relationships of the transistors and the signal terminals change accordingly, and the structure of the third shift sub-module is not limited to that shown in FIG. 7.

Optionally, the shift output module 120 of the shift output portion 13 includes a transistor Ma9, a transistor M10, and a capacitor Ca1. The gate of the transistor Ma9 is electrically connected to the first node N1, the first terminal of the transistor Ma9 is electrically connected to the second power supply terminal VG2, and the second terminal of the transistor Ma9 is electrically connected to the shift output terminal NEXT. The gate of the transistor Ma10 is electrically connected to the second node N2, the first terminal of the transistor Ma10 is electrically connected to the first power supply terminal VG1, and the second terminal of the transistor Ma10 is electrically connected to the shift output terminal NEXT. The first plate of the capacitor Ca1 is electrically connected to the first node N1, and the second plate of the capacitor Ca1 is electrically connected to the second power supply terminal VG2.

Optionally, the transistors Ma1 to Ma16 in the shift output portion 13 in FIG. 7 are all P-type transistors. Accordingly, the first power supply terminal VG1 may be at low level (labeled vgl1), and the second power supply terminal VG2 may be at high level (labeled vgh1). In other embodiments, optionally, at least one transistor in the shift output portion may be an N-type transistor. In addition, the type or number of transistors in the shift output portion can be adaptively adjusted, and the connection relationships of the transistors and the signal terminals change accordingly. The structure of the shift output portion is not limited to that shown in FIG. 7.

The shift control module 110 controls the signal of the first node N1 and the signal of the second node N2 in response to the input signal, the first clock signal, the second clock signal, the first power supply signal vgl1, and the second power supply signal vgh1, so that the signal of the first node N1 undergoes the toggling between high and low levels, and the signal of the second node N2 undergoes the toggling between high and low levels. The shift output module 120 controls one of the first power supply signal vgl1 and the second power supply signal vgh1 to be transmitted to the shift output terminal NEXT in response to the signal of the first node N1, the signal of the second node N2, the first power supply signal vgl1, and the second power supply signal vgh1. Taking the active level of the shift signal being the high level vgh1 as an example.

If the shift control module 110 controls the signal of the first node N1 to be at low level, the transistor Ma9 in the shift output module 120 is turned on, the second power supply signal vgh1 provided by the second power supply terminal VG2 is transmitted to the shift output terminal NEXT, and the shift signal output by the shift output terminal NEXT is an active level.

If the shift control module 110 controls the signal of the first node N1 to be at high level, the transistor Ma9 in the shift output module 120 is turned off, and then the first power supply signal vgl1 provided by the first power supply terminal VG1 can be transmitted to the shift output terminal NEXT through the turned-on transistor Ma10, and the shift signal output by the shift output terminal NEXT is an inactive level.

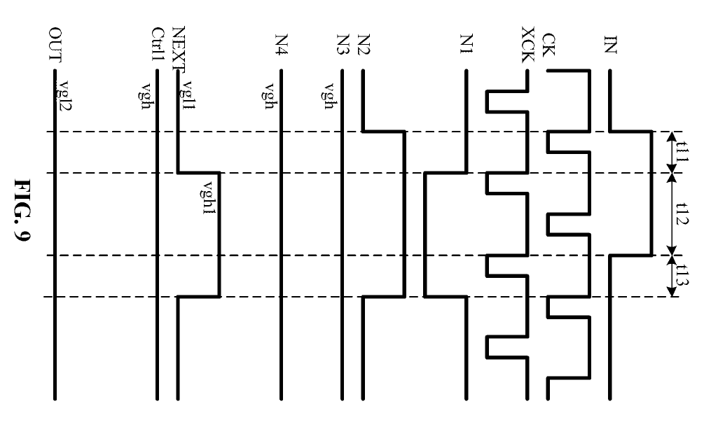

FIG. 8 is a schematic diagram of a shift register according to still yet another embodiment of the present application. Referring to FIGS. 4 and 8, optionally, the first control module 130 includes: a first transistor Mb1; the gate of the first transistor Mb1 is electrically connected to the third node N3, the first terminal of the first transistor Mb1 is electrically connected to the first node N1, and the second terminal of the first transistor Mb1 is electrically connected to the fourth node N4. Optionally, the second control module 140a includes: a second transistor Mb2. The gate of the second transistor Mb2 is electrically connected to the first node N1, the first terminal of the second transistor Mb2 is electrically connected to the third node N3, and the second terminal of the second transistor Mb2 is electrically connected to the fourth node N4. In the present embodiment, optionally, the second terminal of the first transistor Mb1 is directly electrically connected to the fourth node N4.

Optionally, the refresh output module 150 includes: a first output sub-module 151 electrically connected to a fourth node N4, a fourth power supply terminal VG4, and a scan output terminal OUT and configured to control the scan output terminal OUT to output a gate driving signal Gout; and a second output sub-module 152 electrically connected to the second node N2, the third power supply terminal VG3 and the scan output terminal OUT, and configured to control the scan output terminal OUT to output the gate driving signal Gout. Optionally, the first output sub-module 151 includes: a sixth transistor Mb6. The gate of the sixth transistor Mb6 is electrically connected to the fourth node N4, the first terminal of the sixth transistor Mb6 is electrically connected to the fourth power supply terminal VG4, and the second terminal of the sixth transistor Mb6 is electrically connected to the scan output terminal OUT. Optionally, the second output sub-module 152 includes: a seventh transistor Mb7. The gate of the seventh transistor Mb7 is electrically connected to the second node N2, the first terminal of the seventh transistor Mb7 is electrically connected to the third power supply terminal VG3, and the second terminal of the seventh transistor Mb7 is electrically connected to the scan output terminal OUT.

Optionally, the shift register 12 further includes a fourth control module 160; the fourth control module 160 is electrically connected to the second control terminal B. The first refresh signal line SCL1 provides the first refresh control signal Ctrl1 to the third node N3 through the fourth control module 160. The second control terminal B is one of the fifth node N5, the second node N2, and the shift output terminal NEXT. Optionally, the fourth control module 160 includes a fifth transistor Mb5. The gate of the fifth transistor Mb5 is electrically connected to the second control terminal B, the first terminal of the fifth transistor Mb5 is electrically connected to the first refresh signal line SCL1, and the second terminal of the fifth transistor Mb5 is electrically connected to the third node N3.

In other embodiments, the fifth transistor Mb5 may also be a double-gate transistor. By designing the fifth transistor Mb5 as a double-gate transistor, the leakage current of the third node N3 can be reduced. Specifically, when the fifth transistor Mb5 is turned off and the third node N3 is at the high level, the fifth transistor Mb5 is designed as a double-gate transistor, which can stabilize the potential of the third node N3 to the high level in the vicinity of the time node when the first refresh signal line SCL1 jumps from the high level to the low level, reduce the leakage current of the third node N3 at the high level to the first refresh signal line SCL1 at the low level, and improve the operation stability of the shift register 12.

In the present embodiment, the signal of the third node N3 controls the first transistor Mb1 to be turned on or off. When the signal of the third node N3 controls the first transistor Mb1 to be turned on, the signal of the first node N1 is transmitted to the fourth node N4 through the turned on first transistor Mb1. The signal of the first node N1 controls the second transistor Mb2 to be turned on or off. When the signal of the first node N1 controls the second transistor Mb2 to be turned on, the signal of the third node N3 is transmitted to the fourth node N4 through the turned-on second transistor Mb2. It can be seen that the signal of the fourth node N4 is controlled by the first control module 130 and the second control module 140a collectively, and the signal of the fourth node N4 undergoes toggling between high and low levels.

The signal of the fourth node N4 controls the sixth transistor Mb6 to be turned on or off. When the signal of the fourth node N4 controls the sixth transistor Mb6 to be turned on, the fourth power supply signal provided by the fourth power supply terminal VG4 is transmitted to the scan output terminal OUT. The signal of the second node N2 controls the seventh transistor Mb7 to be turned on or off. When the signal of the second node N2 controls the seventh transistor Mb7 to be turned on, the third power supply signal provided by the third power supply terminal VG3 is transmitted to the scan output terminal OUT. When the fourth power supply signal is at the high level vgh2 and the third power supply signal is at the low level vgl2, the gate driving signal Gout output by the shift register 12 is at the high level vgh2 when the sixth transistor Mb6 is turned on, and the gate driving signal Gout output by the shift register 12 is at the low level vgl2 when the seventh transistor Mb7 is turned on.

The signal of the second control terminal B controls the fifth transistor Mb5 to be turned on or off. When the signal of the second control terminal B controls the fifth transistor Mb5 to be turned on, the first refresh signal line SCL1 provides the first refresh control signal Ctrl1 to the third node N3 through the fifth transistor Mb5. The second control terminal B is one of the fifth node N5, the second node N2, and the shift output terminal NEXT. Referring to FIG. 8, the signal of the node N5a is the same as the signal of the fifth node N5, and the signal of the node N2b is the same as the signal of the second node N2. Furthermore, in the same shift register 12, the second control terminal B may be the fifth node N5, the node N5a, the second node N2, the node N2b, or the shift output terminal NEXT. In other embodiments, optionally, the shift register 12 does not include the fourth control module 160, the first refresh signal line SCL1 is directly electrically connected to the third node N3, and the signal of the third node N3 is the first refresh control signal Ctrl1.

In the present embodiment, the first transistor Mb1, the second transistor Mb2, the fifth transistor Mb5, the sixth transistor Mb6, and the seventh transistor Mb7 may all be PMOS. However, they are not limited thereto. On the premise of ensuring the normal operation of the shift register 12, the operation type of the transistors in the shift register 12 can be reasonably selected to be PMOS or NMOS. Accordingly, the third power supply signal received by the third power supply terminal VG3 may be at low level (labeled vgl2), and the fourth power supply signal received by the fourth power supply terminal VG4 may be at high level (labeled vgh2). Optionally, the active level of the gate driving signal Gout provided by the scan output terminal OUT is a high level vgh2, and the inactive level of the gate driving signal Gout is a low level vgl2. Optionally, the active level of the shift signal provided by the shift output terminal NEXT is a high level vgh1, and the inactive level of the shift signal is a low level vgl1. In this embodiment, the operation principle of the shift register 12 is explained by taking an example where the second control terminal B of the shift register 12 is electrically connected to the shift output terminal NEXT.

Optionally, the level signal provided by the first power supply terminal VG1 is different from the level signal provided by the third power supply terminal VG3. Optionally, the level signal provided by the first power supply terminal VG1 is less than or equal to the level signal provided by the third power supply terminal VG3. Referring to FIG. 8, the first power supply signal provided by the first power supply terminal VG1 is a low level vgl1, and the third power supply signal provided by the third power supply terminal VG3 is a low level vgl2, and the first power supply signal vgl1 and the third power supply signal vgl2 may be different. Specifically, the first power supply signal vgl1 is less than or equal to the third power supply signal vgl2. If leakage current occurs at the second node N2, the first power supply signal vgl1 is smaller than the third power supply signal vgl2, and the transistor Ma10 and the seventh transistor Mb7 can be ensured to be turned on and off normally, which avoids the situation where leakage current from the second node N2 occurs and the transistor Ma10 and the seventh transistor Mb7 are erroneously controlled. The normal and stable operation of the shift register 12 is ensured.

Optionally, the display panel has a multi-frequency refresh mode. In the multi-frequency refresh mode, the display area of the display panel includes at least a first display partition and a second display partition, a refresh frequency of the first display partition is a first refresh frequency, a refresh frequency of the second display partition is a second refresh frequency, and the first refresh frequency is less than the second refresh frequency.

Optionally, in the multi-frequency refresh mode, the frequency of the shift signal of the shift register in the first display partition is greater than the frequency of the gate driving signal. In the multi-frequency refresh mode, the frequency of the gate driving signal of the shift register in the first display partition is less than the frequency of the gate driving signal of the shift register in the second display partition. Accordingly, the first display partition operates at a low frequency and the second display partition operates at a high frequency. Optionally, in the multi-frequency refresh mode, the frequency of the shift signal of the shift register in the second display partition may be equal to the frequency of the gate driving signal, which is not limited thereto.

Exemplarily, in the multi-frequency refresh mode, the first refresh frequency of the first display partition is 30 Hz, and the second refresh frequency of the second display partition is 120 Hz. Taking an example that the refresh frequency of the display panel is 120 Hz. Then, in the multi-frequency refresh mode, in the first display partition, the frequency of the shift signal of the shift register is 120 Hz and the frequency of the gate driving signal is 30 Hz; in the second display partition, the frequency of the shift signal of the shift register is 120 Hz and the frequency of the gate driving signal is 120 Hz.

Exemplarily, in the multi-frequency refresh mode, the first refresh frequency of the first display partition is 30 Hz, and the second refresh frequency of the second display partition is 60Hz. Taking an example that the refresh frequency of the display panel is 120 Hz. Then, in the multi-frequency refresh mode, in the first display partition, the frequency of the shift signal of the shift register is 120 Hz and the frequency of the gate driving signal is 30 Hz; in the second display partition, the frequency of the shift signal of the shift register is 120 Hz and the frequency of the gate driving signal is 60 Hz.

Optionally, the operation process of the shift register 12 includes a data writing stage and a data holding stage. In the data writing stage, the first refresh control signal Ctrl1 provided by the first refresh signal line SCL1 to the shift register 12 is an active level. In the data holding stage, the first refresh control signal Ctrl1 provided by the first refresh signal line SCL1 to the shift register 12 is an inactive level.

It should be understood that a data holding stage is provided between two adjacent data writing stages of the shift register 12. In the multi-frequency refresh mode, since the first refresh frequency of the first display partition is less than the second refresh frequency of the second display partition, in one frame, the duration of the data holding stage of the shift register 12 in the first display partition is longer than the duration of the data holding stage of the shift register 12 in the second display partition.

In this embodiment, by adding the second control module 140a, the potential of the fourth node N4 can be stabilized, and the output of any shift register 12 in the first display partition operating at a low frequency can be stabilized and effective, and the output of any shift register 12 in the second display partition operating at a high frequency can be stabilized and effective. Regardless of low-frequency operation or high-frequency operation, the shift registers 12 do not have a problem of output failure or poor stability caused by potential reduction due to leakage current from the fourth node N4 to other nodes.

In this embodiment, the operation principle of the shift register 12 is described by taking an example that the active level of the first refresh control signal Ctrl1 is the low level vgl and the inactive level of the first refresh control signal Ctrl1 is the high level vgh.

FIG. 9 is a low-frequency operation timing diagram of the shift register 12 in the first display partition shown in FIG. 8. Referring to FIGS. 8 and 9, in the first display partition, if the shift signal frequency of the shift register 12 is greater than the gate driving signal frequency, the shift signal of the shift register 12 is an active level and the gate driving signal of the shift register 12 is an inactive level, thereby realizing low-frequency operation. Therefore, in the operation condition of the shift register 12 in the first display partition shown in FIG. 9, in the stages t11 to t13, the first refresh control signal Ctrl1 is at the high level vgh, that is, the inactive level, so that the shift register 12 satisfies the situation where the shift signal is the active level and the gate driving signal is the inactive level.

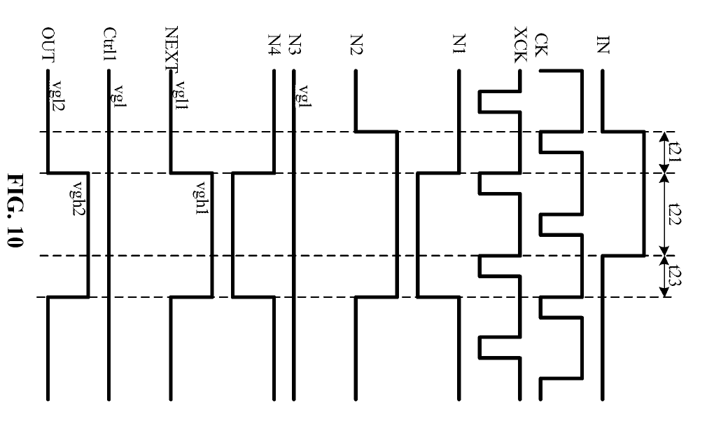

FIG. 10 is a high-frequency operation timing diagram of the shift register 12 in the second display partition shown in FIG. 8. Referring to FIGS. 8 and 10, optionally, in the second display partition, if the shift signal frequency of the shift register 12 is equal to the gate driving signal frequency, then the shift signal of the shift register 12 is an active level and the gate driving signal of the shift register 12 is an active level, thereby realizing high-frequency operation. Therefore, for the operation situation of the shift register 12 in the second display partition shown in FIG. 10, in the stages t21 to t23, the first refresh control signal Ctrl1 is at the low level vgl, that is, the active level, so that the shift register 12 satisfies the situation where the shift signal is the active level and the gate driving signal is the active level.

In other embodiments, the shift register includes a data writing stage and a data holding stage, the stages t11 to t13 may also be regarded independently as a data holding stage of the shift register, and the stages t21 to t23 may also be regarded independently as a data writing stage of the shift register.

Referring to FIGS. 8 and 9, the low-frequency operation process of the shift register 12 includes the following the stages.

In the phase t11, the first clock signal provided by the first clock terminal CK jumps from a low level to a high level, accordingly, the transistor Ma4 and the transistor Ma13 are turned on first and then turned off synchronously, the input signal provided by the input terminal IN is at high level, and then the fifth node N5 and the node N5a are both at high level, and the transistor Ma2 and the transistor Ma6 are both turned off; when the transistor Ma15 and the transistor Ma16 are turned on, the second node N2 and the node N2b are both at high level, and the transistor Ma10 is turned off; the low level vgl1 is sequentially transmitted to the node N6a and the node N6b through the transistor Ma5 and the transistor Ma8, and the transistor Ma3 is turned on; the second clock signal provided by the second clock terminal XCK is at high level, so that the transistor Ma7 is turned off, the first node N1 remains at the high level of the previous stage, and the transistor Ma9 is turned off; the shift signal of the shift output terminal NEXT remains at the low level vgl1 of the previous stage, that is, the inactive level; when the transistor Mb5 is turned on and the high level vgh of the first refresh control signal Ctrl1 is transmitted to the third node N3, the third node N3 is at the high level vgh, the transistor Mb1 and the transistor Mb2 are turned off, and under the coupling of the high level of the third node N3, the fourth node N4 can be stabilized at the high level vgh of the previous stage, so that the transistor Mb6 is turned off; the transistor Mb7 is turned off, and the gate driving signal Gout of the scan output terminal OUT remains at the low level vgl2.

In the stages t12 to t13, the stages t12 to t13 are also the active level output stages of the shift signal of the shift register 12, both the fifth node N5 and the node N5a remain at the high level, the second node N2 and the node N2b are both at the high level, and the transistor Ma10 is turned off; the node N6a and the node N6b are at the low level vgl1, so that the transistor Ma3 is turned on; when the second clock signal provided by the second clock terminal XCK is at low level, the transistor Ma7 is turned on, and the low level of the second clock signal is transmitted to the node N6c and the first node N1, so that the first node N1 is at low level, when the second clock signal provided by the second clock terminal XCK is at high level, the transistor Ma7 is turned off to enable the first node N1 to be maintained at low level; the transistor Ma9 is turned on, the second power supply signal vgh1 provided by the second power supply terminal VG2 is transmitted to the shift output terminal NEXT, and the shift signal is at high level vgh1, that is, an active level; the transistor Mb5 is turned off, the third node N3 remains at the high level vgh of the previous stage, and the transistor Mb1 is turned off; the first node N1 is at low level, so that the transistor Mb2 is turned on, the fourth node N4 can be stabilized at high level vgh under the action of the third node N3, so that the leakage current from the fourth node N4 to the first node N1 can be reduced, and the problem that the potential is gradually reduced due to the leakage current from the fourth node N4 to the first node N1 is improved, and the transistor Mb6 is turned off; the transistor Mb7 is turned off, and the gate driving signal Gout of the scan output terminal OUT remains at low level vgl2, that is, an inactive level. It can be seen that in this stage, the shift signal is the active level and the gate driving signal Gout is the inactive level.

After the phase t13, the fifth node N5 and the node N5a are at low level. Accordingly, the second node N2 and the node N2b are both at low level, the transistor Ma10 is turned on, and the shift signal of the shift output terminal NEXT is at low level vgl1. The transistor Ma6 is turned on, so that the first node N1 is at high level vgh1, and the transistor Ma9 is turned off. The transistor Mb5 is turned on. When the signal Ctrl1 of the first refresh signal line SCL1 undergoes toggling between high and low levels, the third node N3 undergoes toggling between high and low levels to switch the on-off state of the transistor Mb1, the high level of the first node N1 is written to the fourth node N4 when the transistor Mb1 is turned on, so that the signal of the fourth node N4 is at high level, and the transistor Mb6 is controlled to be turned off. Alternatively, if the signal Ctrl1 of the first refresh signal line SCL1 remains at high level, the third node N3 is at high level, so that the transistor Mb1 and the transistor Mb2 are turned off, under the coupling of the third node N3, the fourth node N4 may be stabilized at high level vgh, so that the transistor Mb6 is turned off. The transistor Mb7 is turned on, and the gate driving signal Gout of the scan output terminal OUT is at low level vgl2.

As described above, when the shift register 12 operates in the low-frequency mode, the high-level signal provided by the first refresh signal line SCL1 enables the third node N3 to be maintained at the high level vgh, especially for the stages t12 to t13, the first node N1 is at the low level and the transistor Mb1 is turned off, then the high level of the third node N3 can be written to the fourth node N4 by the newly added second control module 140a, the high level of the fourth node N4 is maintained, and the transistor Mb6 is controlled to be turned off, so as to prevent the problem that the transistor Mb6 is erroneously turned on caused by the potential being reduced gradually due to the leakage current from the fourth node N4 to the first node N1, so that the gate driving signal Gout of the scan output terminal OUT remains at the low level vgl2, thereby effectively enhancing the circuit stability and efficiency of the shift register 12 operating in the low-frequency mode.

Referring to FIGS. 8 and 10, the high-frequency operation process of the shift register 12 includes the following the stages.

In the phase t21, the first clock signal provided by the first clock terminal CK jumps from a low level to a high level, and accordingly, the transistor Ma4 and the transistor Ma13 are turned on first and then turned off synchronously, and the input signal provided by the input terminal IN is at high level, and then the fifth node N5 and the node N5a are both at high level, and the transistor Ma2 and the transistor Ma6 are both turned off; the transistor Ma15 and the transistor Ma16 are turned on, and then the second node N2 and the node N2b are both at high level, and the transistor Ma10 is turned off; the low level vgl1 is sequentially transmitted to the node N6a and the node N6b through the transistor Ma5 and the transistor Ma8, and the transistor Ma3 is turned on; the second clock signal provided by the second clock terminal XCK is at high level, so that the transistor Ma7 is turned off, the first node N1 remains the high level of the previous stage, and the transistor Ma9 is turned off; the shift signal of the shift output terminal NEXT remains at the low level vgl1 of the previous stage, that is, the inactive level; the transistor Mb5 is turned on, the low level vgl of the first refresh control signal Ctrl1 is transmitted to the third node N3, and then the third node N3 is at the low level vgl, the transistor Mb1 is turned on and the transistor Mb2 is turned off, the high level of the first node N1 is transmitted to the fourth node N4, so that the fourth node N4 is stabilized at the high level, and the transistor Mb6 is turned off; the transistor Mb7 is turned off, and the gate driving signal Gout of the scan output terminal OUT remains at the low level vgl2 of the previous stage, that is, the inactive level.

In the stages t22 to t23, the stages t22 to t23 are also the active level output stages of the shift signal of the shift register 12, both the fifth node N5 and the node N5a remain at the high level, the second node N2 and the node N2b are both at the high level, and the transistor Ma10 is turned off; the node N6a and the node N6b are at the low level vgl1, so that the transistor Ma3 is turned on; when the second clock signal provided by the second clock terminal XCK is at low level, the transistor Ma7 is turned on, and the low level of the second clock signal is transmitted to the node N6c and the first node N1, so that the first node N1 is at low level, when the second clock signal provided by the second clock terminal XCK is at high level, the transistor Ma7 is turned off, so that the first node N1 is maintained at low level; the transistor Ma9 is turned on, the second power supply signal vgh1 provided by the second power supply terminal VG2 is transmitted to the shift output terminal NEXT, and the shift signal is at high level vgh1, that is, an active level; the transistor Mb5 is turned off, the third node N3 remains at the low level vgl of the previous stage, the transistor Mb1 and the transistor Mb2 are turned on, the fourth node N4 is at the low level, the transistor Mb6 is turned on, the transistor Mb7 is turned off, the fourth power supply signal vgh2 provided by the fourth power supply terminal VG4 is transmitted to the scan output terminal OUT, and the gate driving signal Gout is at the high level vgh2, that is, the active level. It can be seen that in this stage, the shift signal is the active level and the gate driving signal Gout is the active level.

After the phase t23, the fifth node N5 and the node N5a are at low level, and accordingly, the second node N2 and the node N2b are both at low level, the transistor Ma10 is turned on, the first power supply signal vgl1 provided by the first power supply terminal VG1 is transmitted to the shift output terminal NEXT, and the shift signal of the shift output terminal NEXT is at low level vgl1, that is, an inactive level; the transistor Ma6 is turned on, so that the first node N1 is at the high level vgh1, and the transistor Ma9 is turned off; the transistor Mb5 is turned on and the transistor Mb2 is turned off; if the signal Ctrl1 of the first refresh signal line SCL1 remains at low level, then the third node N3 is at low level to enable the transistor Mb1 to be turned on, or, if the signal Ctrl1 of the first refresh signal line SCL1 undergoes the toggling between high and low levels, the third node N3 undergoes the toggling between high and low levels to switch the on-off state of the transistor Mb1; the high level of the first node N1 is written to the fourth node N4 when the transistor Mb1 is turned on, so that the signal of the fourth node N4 is at the high level, and the transistor Mb6 is controlled to be turned off; the transistor Mb7 is turned on, the third power supply signal vgl2 provided by the third power supply terminal VG3 is transmitted to the scan output terminal OUT, and the gate driving signal Gout is at low level vgl2, that is, an inactive level.

As described above, when the shift register 12 operates in the high-frequency mode, the newly added second control module 140a does not affect the normal operation of the circuit, thereby ensuring the circuit stability and validity of the shift register 12 operating in the high-frequency mode.

In this embodiment, the second control module 140a is additionally disposed in the shift register 12, and the second control module 140a can stabilize the potential of the fourth node N4, reduce the leakage current to the first node N1 caused by the interference of the first control module 130 on the high level of the fourth node N4, and further avoid the problem of erroneous control of the refresh output module 150 caused by the leakage current of the fourth node N4, thereby improving the output stability of the gate driving signal Gout and the potential stability of the fourth node N4 of the shift register 12, which is conducive to ensuring the output validity, accuracy, and stability of the shift register 12, and further improving the display quality of the display panel.

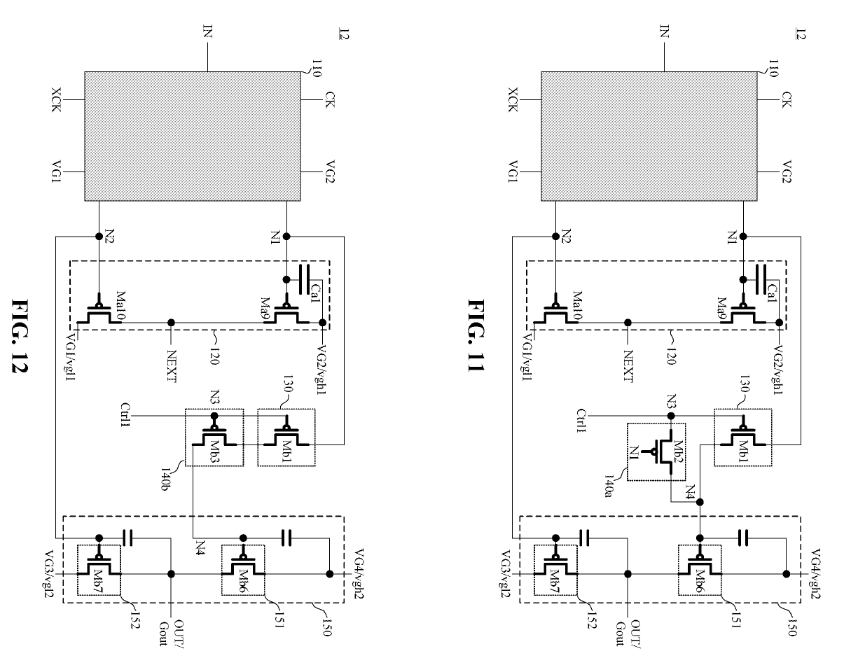

FIG. 11 is a schematic diagram of a shift register according to even still yet another embodiment of the present application, and is different from FIG. 8 in that the third node N3 in FIG. 11 is directly electrically connected to the first refresh signal line SCL1.

Reference can be made to FIG. 9 for the low-frequency operation timing of the shift register 12 in FIG. 11. Specifically, taking stages t12 to t13 as an example for explanation, in the stages t12 to t13, the first node N1 is at low level, the second node N2 is at high level, the second power supply signal vgh1 provided by the second power supply terminal VG2 is transmitted to the shift output terminal NEXT through the turned-on transistor Ma9, and then the shift signal is at high level vgh1, that is, an active level. When the first refresh signal line SCL1 is directly electrically connected to the third node N3, and the third node N3 is at the high level of the first refresh control signal Ctrl1. The transistor Mb1 is turned off and the transistor Mb2 is turned on, the high level of the third node N3 is transmitted to the fourth node N4, so that the transistor Mb6 is turned off. The gate driving signal Gout of the scan output terminal OUT remains at the low level vgl2 of the previous stage, that is, the inactive level. It can be seen that the first refresh signal line SCL1 directly provides the first refresh control signal Ctrl1 to the third node N3. When the shift signal output from the shift register 12 is an active level, the gate driving signal Gout may be an inactive level, thereby realizing low-frequency operation.

Reference can be made to FIG. 10 for the high-frequency operation timing of the shift register 12 in FIG. 11. Specifically, taking stages t22 to t23 as an example for explanation, in the stages t22 to t23, the first node N1 is at low level, the second node N2 is at high level, the second power supply signal vgh1 is transmitted to the shift output terminal NEXT, and the shift signal is at high level vgh1, that is, an active level. The low level of the first refresh control signal Ctrl1 is written to the third node N3; the transistor Mb1 is turned on and the transistor Mb2 is turned on, and then the fourth node N4 is at low level; the transistor Mb6 is turned on, the transistor Mb7 is turned off, the fourth power supply signal vgh2 is transmitted to the scan output terminal OUT, and the gate driving signal Gout is at high level vgh2, that is, an active level. It can be seen that the first refresh signal line SCL1 directly provides the first refresh control signal Ctrl1 to the third node N3. When the shift signal output from the shift register 12 is an active level, the gate driving signal Gout can be an active level, thereby realizing high-frequency operation.

FIG. 12 is a schematic diagram of a shift register according to even still yet another embodiment of the present application. Referring to FIGS. 5 and 12, optionally, the second control module 140b includes: a third transistor Mb3. The gate of the third transistor Mb3 is electrically connected to the third node N3, the first terminal of the third transistor Mb3 is electrically connected to the first control module 130, and the second terminal of the third transistor Mb3 is electrically connected to the fourth node N4. Specifically, the second control module 140b is electrically connected between the first control module 130 and the fourth node N4. The second control module 140b shown in FIG. 12 is different from the second control module 140a shown in FIG. 8.

Optionally, the third transistor Mb3 is of the same type as the first transistor Mb1, exemplarily, both are PMOS, and the signal of the third node N3 controls the third transistor Mb3 and the first transistor Mb1 to be turned on or off simultaneously. It can be understood that the first transistor Mb1 and the third transistor Mb3 can be regarded as a double-gate transistor.

Reference can be made to FIG. 9 for the low-frequency operation timing of the shift register 12 in FIG. 12. Specifically, taking stages t12 to t13 as an example for explanation, in the stages t12 to t13, the first node N1 is at low level, the second node N2 is at high level, and the shift signal output by the shift output terminal NEXT is the second power supply signal vgh1, that is, the active level. The high level of the first refresh control signal Ctrl1 is written to the third node N3, so that the double-gate transistor (Mb1 + Mb3) is turned off, and the fourth node N4 is in the floating state and maintained at the high level of the previous stage. The double-gate transistor (Mb1+Mb3) is provided between the fourth node N4 and the first node N1, which can reduce the leakage current from the fourth node N4 to the first node N1. Therefore, in this stage, the leakage current from the fourth node N4 to the first node N1 is reduced by disposing the second control module 140b, so that the fourth node N4 can also be stabilized at high level to control the transistor Mb6 to be turned off. The gate driving signal Gout of the scan output terminal OUT remains at low level vgl2, that is, an inactive level. It can be seen that when the first node N1 is at the low level, the fourth node N4 is at the high level, and the first transistor Mb1 is turned off, the leakage current from the fourth node N4 to the first node N1 can be reduced by disposing the second control module 140b between the output terminal of the first transistor Mb1 and the fourth node N4, thereby improving the output stability of the shift register 12.

Reference can be made to FIG. 10 for the high-frequency operation timing of the shift register 12 in FIG. 12. Specifically, taking stages t22 to t23 as an example for explanation, in the stages t22 to t23, the first node N1 is at low level, the second power supply signal vgh1 is transmitted to the shift output terminal NEXT, and the shift signal is at high level vgh1, that is, an active level. When the low level of the first refresh control signal Ctrl1 is written to the third node N3, so that the double-gate transistor (Mb1+Mb3) is turned on, the fourth node N4 is at the low level, the fourth power supply signal vhg2 is transmitted to the scan output terminal OUT, and the gate driving signal Gout is at the high level vgh2, that is, the active level. It can be seen that when the double-gate transistor (Mb1+Mb3) is designed, the shift signal output from the shift register 12 is the active level, and the gate driving signal Gout can be the active level, thereby realizing high-frequency operation.

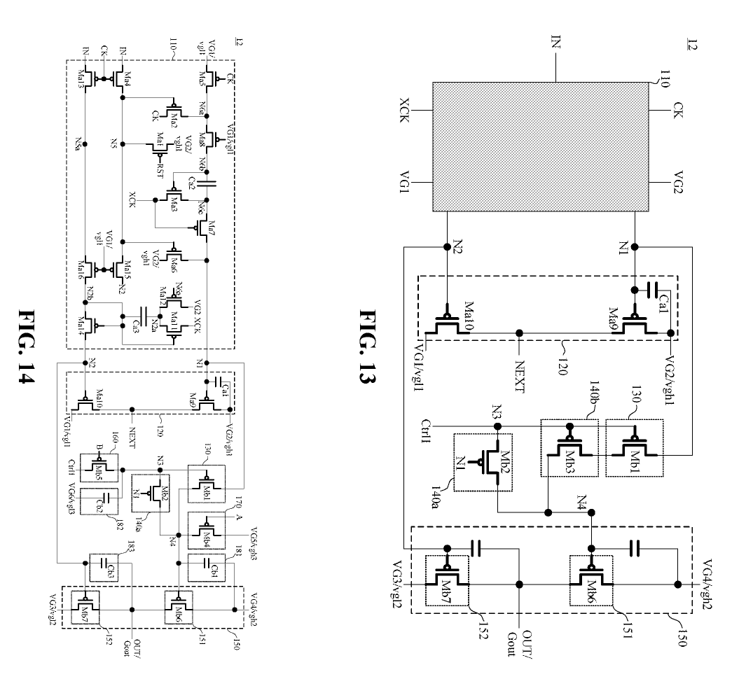

FIG. 13 is a schematic diagram of a shift register according to even still yet another embodiment of the present application. Referring to FIGS. 3 and 13, optionally, the shift register 12 includes a second control module 140a and a second control module 140b, the second control module 140a includes a second transistor Mb2, and the second control module 140b includes a third transistor Mb3. The gate of the second transistor Mb2 is electrically connected to the first node N1, the first terminal of the second transistor Mb2 is electrically connected to the third node N3, and the second terminal of the second transistor Mb2 is electrically connected to the fourth node N4. The gate of the third transistor Mb3 is electrically connected to the third node N3, the first terminal of the third transistor Mb3 is electrically connected to the first control module 130, and the second terminal of the third transistor Mb3 is electrically connected to the fourth node N4.

The first transistor Mb1 and the third transistor Mb3 may be of the same type, and the second transistor Mb2 and the third transistor Mb3 may be of the same type or may be of different types. Exemplarily, the three are all PMOS, and the third node N3 controls the third transistor Mb3 and the first transistor Mb1 to be turned on or off simultaneously. It can be understood that the first transistor Mb1 and the third transistor Mb3 can be regarded as a double-gate transistor, which is not limited thereto. The operation type of each transistor in the shift register 12 can be reasonably selected on the premise of ensuring the normal operation of the shift register 12.

Reference can be made to FIG. 9 for the low-frequency operation timing of the shift register 12 in FIG. 13, and reference can be made to FIG. 10 for the high-frequency operation timing of the shift register 12 in FIG. 13.

In FIG. 13, when the double-gate transistor (Mb1+Mb3) is turned off, the first node N1 is at low level and the fourth node N4 is at high level, the double-gate transistor (Mb1+Mb3) can reduce the leakage current from the fourth node N4 to the first node N1, the high level of the third node N3 can further reduce the leakage current from the fourth node N4 to the first node N1 by pulling up the potential of the fourth node N4 through the second transistor Mb2, so that the fourth node N4 can be stabilized at high level in low-frequency operation to control the transistor Mb6 to be turned off, ensuring the gate driving signal Gout at the scan output terminal OUT remains at the low level vgl2, that is, an inactive level. The leakage current from the fourth node N4 to the first node N1 can be reduced by disposing the second control module 140a and the second control module 140b simultaneously, thereby improving the output stability of the shift register 12.

In other embodiments, a fourth control module 160 (as shown in FIG. 8) may be further added in FIGS. 12 and 13, and the third node N3 is electrically connected to the first refresh signal line SCL1 through the fourth control module 160, thereby further improving the output stability of the shift register 12.

In this embodiment, the additional second control module 140 can stabilize the potential of the fourth node N4, improve the problem of current leakage caused by the interference of the first control module 130 on the high level of the fourth node N4, and further avoid the problem of erroneous control of the refresh output module 150 caused by the leakage current of the fourth node N4, thereby improving the output stability of the gate driving signal Gout and the potential stability of the fourth node N4 of the shift register 12, which is conducive to ensuring the output validity, accuracy, and stability of the shift register 12, and further improving the display quality of the display panel.

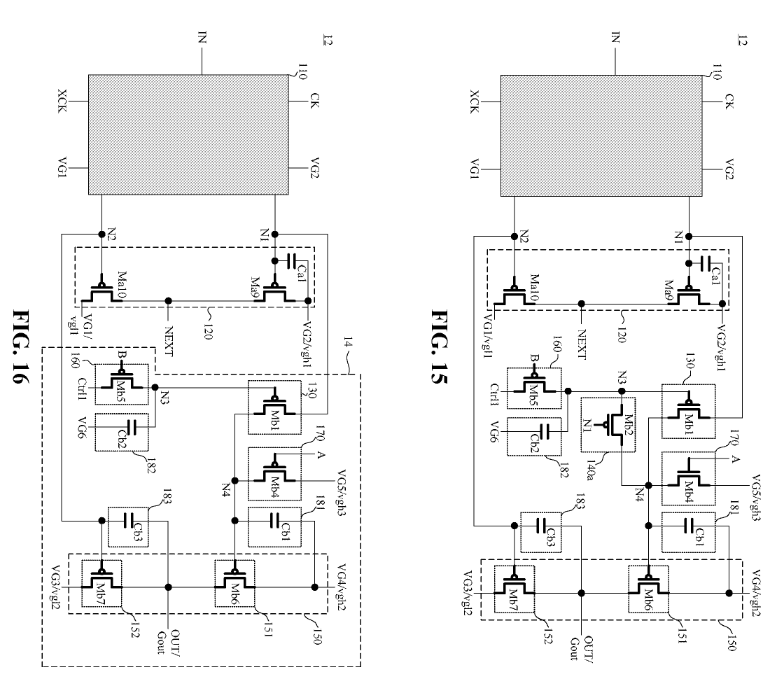

FIG. 14 is a schematic diagram of a shift register according to even still yet another embodiment of the present application. As shown in FIG. 14, optionally, the shift register 12 further includes: a third control module 170 electrically connected to the fifth power supply terminal VG5, the first control terminal A, and the fourth node N4, and configured for controlling a signal of the fourth node N4. The first control terminal A is one of the fifth node N5, the second node N2, the shift output terminal NEXT, and the third node N3. The third control module 170 includes: a fourth transistor Mb4. The gate of the fourth transistor Mbb is electrically connected to the first control terminal A, the first terminal of the fourth transistor Mb4 is electrically connected to the fifth power supply terminal VG5, and the second terminal of the fourth transistor Mb4 is electrically connected to the fourth node N4.

In this embodiment, the signal of the first control terminal A controls the fourth transistor Mb4 to be turned on or off. When the signal of the first control terminal A controls the fourth transistor Mb4 to be turned on, the fifth power supply signal provided by the fifth power supply terminal VG5 is transmitted to the fourth node N4 through the turned-on fourth transistor Mb4, so as to adjust the signal of the fourth node N4. Specifically, since the signal of the node N5a is the same as the signal of the fifth node N5, and the signal of the node N2b is the same as the signal of the second node N2, therefore, in the same shift register 12, the first control terminal A may be the fifth node N5, the node N5a, the second node N2, the node N2b, the shift output terminal NEXT, or the third node N3.

Optionally, the fourth transistor Mb4 is PMOS. The fifth power supply signal provided by the fifth power supply terminal VG5 is at high level vgh3. Accordingly, when the signal of the fourth node N4 is at high level, regardless of whether the fourth transistor Mb4 is turned on or off, the fifth power supply signal vgh3 provided by the fifth power supply terminal VG5 can stabilize the potential of the fourth node N4, so that the fourth node N4 is maintained at high level, the leakage current of the fourth node N4 is reduced, and the problem of leakage current from the fourth node N4 to the fifth power supply terminal VG5 does not occur, and the sixth transistor Mb6 is ensured to be turned off. When the signal of the fourth node N4 is at low level, the first control terminal A controls the fourth transistor Mb4 to be turned off, and the low level of the fourth node N4 controls the sixth transistor Mb6 to be turned on. In this way, the third control module 170 is additionally disposed in the shift register 12, which does not affect the normal operation of the shift register 12, and can improve the output stability and validity of the shift register 12, which are not limited thereto. The signal of the signal terminal and the operation type of each transistor in the shift register 12 can be reasonably selected on the premise of ensuring the normal operation of the shift register 12.

Optionally, the level signal vgh3 provided by the fifth power supply terminal VG5 is different from the level signal vgh2 provided by the fourth power supply terminal VG4. Optionally, the level signal vgh3 provided by the fifth power supply terminal VG5 is greater than or equal to the level signal vgh2 provided by the fourth power supply terminal VG4.

During the operation of the shift register 12, when the fourth node N4 is at high level, the sixth transistor Mb6 is controlled to be turned off to ensure that the output of the scan output terminal OUT is at low level. In this embodiment, if the fourth power supply signal vgh2 provided by the fourth power supply terminal VG4 is designed to be lower than the fifth power supply signal vgh3 provided by the fifth power supply terminal VG5, when the high level of the fourth node N4 is slightly decreased or disturbed due to leakage current of the fourth node N4, external electric field interference, or other signal interference, the sixth transistor Mb6 can be ensured to remain off, thereby ensuring the output validity and stability of the shift register 12.

Referring to FIG. 14, optionally, at least two of the level signal provided by the second power supply terminal VG2, the level signal provided by the fourth power supply terminal VG4, and the level signal provided by the fifth power supply terminal VG5 are the same signal.

In the present embodiment, the second power supply signal provided by the second power supply terminal VG2 may be at high level vgh1, the fourth power supply signal provided by the fourth power supply terminal VG4 may be at high level vgh2, and the fifth power supply signal provided by the fifth power supply terminal VG5 may be at high level vgh3.

Optionally, the same signal line can be used to simultaneously provide the power supply signals to the second power supply terminal VG2, the fourth power supply terminal VG4, and the fifth power supply terminal VG5, and then the second power supply signal vgh1 is equal to the fourth power supply signal vgh2 and equal to the fifth power supply signal vgh3. In other embodiments, optionally, two different signal lines can be used to provide the power supply signals to the second power supply terminal VG2, the fourth power supply terminal VG4, and the fifth power supply terminal VG5. Exemplarily, one signal line is used to provide the same power supply signal to the second power supply terminal VG2 and the fourth power supply terminal VG4, and the other signal line is used to provide the power supply signal to the fifth power supply terminal VG5. In this way, the number of signal lines in the non-display area can be reduced, which is conducive to realizing the narrow border.

Optionally, the shift register further includes a first coupling module. The first terminal of the first coupling module is electrically connected to one of the second power supply terminal, the fourth power supply terminal, and the fifth power supply terminal, and a second terminal of the first coupling module is electrically connected to the fourth node. Optionally, the first coupling module includes a first capacitor. The first plate of the first capacitor is a first terminal of the first coupling module, and the second plate of the first capacitor is electrically connected to the fourth node. Referring to FIG. 14, the first coupling module 181 includes a first capacitor Cb1. Exemplarily, the first capacitor Cb1 is electrically connected between the fourth power supply terminal VG4 and the fourth node N4.

Optionally, the shift register further includes a second coupling module. The first terminal of the second coupling module is electrically connected to the sixth power supply terminal, and the second terminal of the second coupling module is electrically connected to the third node. Optionally, the second coupling module includes a second capacitor. The first plate of the second capacitor is electrically connected to the sixth power supply terminal, and the second plate of the second capacitor is electrically connected to the third node. Referring to FIG. 14, the second coupling module 182 includes a second capacitor Cb2. Exemplarily, the second capacitor Cb2 is electrically connected between the sixth power supply terminal VG6 and the third node N3.

In the present embodiment, optionally, the sixth power supply signal provided by the sixth power supply terminal VG6 is at low level vgl3. Optionally, the first power supply signal provided by the first power supply terminal VG1 is at low level vgl1, and the third power supply signal provided by the third power supply terminal VG3 is at low level vgl2. Based on this, at least two of the level signal vgl1 provided by the first power supply terminal VG1, the level signal vgl2 provided by the third power supply terminal VG3, and the level signal vgl3 provided by the sixth power supply terminal VG6 are the same signal, that is, at least two of the first power supply terminal VG1, the third power supply terminal VG3, and the sixth power supply terminal VG6 are electrically connected to the same signal line. In this way, the number of signal lines in the non-display area can be reduced, which is conducive to realizing the narrow border.

In other embodiments, the sixth power supply signal provided by the sixth power supply terminal may be at high level. Based on this, optionally, the level signal provided by the sixth power supply terminal and the level signal provided by the second power supply terminal are the same signal. Alternatively, the level signal provided by the sixth power supply terminal and the level signal provided by the fourth power supply terminal are the same signal. Specifically, the same second power supply signal vgh1 is provided to the sixth power supply terminal and the second power supply terminal using the same signal line. Alternatively, the same fourth power supply signal vgh2 is provided to the sixth power supply terminal and the fourth power supply terminal using the same signal line. In this way, the number of signal lines in the non-display area can be reduced, which is conducive to realizing the narrow border. In other embodiments, optionally, the level signal provided by the sixth power supply terminal and the level signal provided by the fifth power supply terminal are the same signal.

Optionally, the shift register further includes a third coupling module. A first terminal of the third coupling module is electrically connected to the scan output terminal, and a second terminal of the third coupling module is electrically connected to the second node. Optionally, the third coupling module includes a third capacitor. The first plate of the third capacitor is electrically connected to the scan output terminal, and the second plate of the third capacitor is electrically connected to the second node. Referring to FIG. 14, the third coupling module 183 includes a third capacitor Cb3. Exemplarily, the third capacitor Cb3 is electrically connected between the scan output terminal OUT and the second node N2.

In FIG. 14, optionally, the second control terminal B is electrically connected to the shift output terminal NEXT, and the first control terminal A is electrically connected to the second node N2.

Reference can be made to FIG. 9 for the low-frequency operation timing of the shift register 12 in FIG. 14. Specifically, taking the stages t12 to t13 as an example for explanation.

In the stages t12 to t13 of low-frequency operation, the first node N1 is at low level, the second node N2 is at high level, the second power supply signal vgh1 provided by the second power supply terminal VG2 is transmitted to the shift output terminal NEXT through the turned-on transistor Ma9, and then the shift signal is at the high level vgh1, that is, an active level; the fifth transistor Mb5 is turned off, the third node N3 is maintained at the high level of the previous stage, and then the transistor Mb1 is turned off; the transistor Mb2 is turned on, the second node N2 is at high level, so that the fourth transistor Mb4 is turned off, and then the high level of the third node N3 is transmitted to the fourth node N4, so that the fourth node N4 is maintained at high level; the transistor Mb6 is turned off, and the gate driving signal Gout of the scan output terminal OUT is maintained at low level vgl2, that is, an inactive level.

After the phase t13 of low-frequency operation, the first node N1 is at high level, the second node N2 is at low level, the first power supply signal vgl1 provided by the first power supply terminal VG1 is transmitted to the shift output terminal NEXT through the turned-on transistor Ma10, and then the shift signal is at low level vgl1, that is, an inactive level; the fifth transistor Mb5 is turned on, the high level of the first refresh control signal Ctrl1 is transmitted to the third node N3, and then the transistor Mb1 is turned off; the transistor Mb2 is turned off, the second node N2 is at low level, so that the fourth transistor Mb4 is turned on, the fifth power supply signal vgh3 provided by the fifth power supply terminal VG5 is transmitted to the fourth node N4, so that the fourth node N4 is at high level; the transistor Mb6 is turned off and the transistor Mb7 is turned on, and the gate driving signal Gout of the scan output terminal OUT is at low level vgl2, that is, an inactive level.

Reference can be made to FIG. 10 for the high-frequency operation timing of the shift register 12 in FIG. 14, and the description thereof will not be repeated here.

In this embodiment, the potential of the fourth node N4 can be stabilized by additionally disposing the second control module 140a and the third control module 170, which reduces the leakage current to the first node N1 caused by the interference of the first control module 130 on the high level of the fourth node N4, and further avoids the problem of erroneous control of the refresh output module 150 caused by the leakage current of the fourth node N4, thereby improving the output stability of the gate driving signal Gout and the potential stability of the fourth node N4 of the shift register 12, which is conducive to ensuring the output validity, accuracy, and stability of the shift register 12, and further improving the display quality of the display panel.

In other embodiments, the types of transistors in the shift register may all be NMOS, or the types of transistors in the shift register may include at least one NMOS and at least one PMOS. Exemplarily, FIG. 15 is a schematic diagram of a shift register according to even still yet another embodiment of the present application, and as shown in FIG. 15, optionally, the first control terminal A is a third node N3. The signal of the third node N3 controls the first control module 130 and the third control module 170 to be turned on in a time-sharing manner. Specifically, the first transistor Mb1 in the first control module 130 is PMOS and the fourth transistor Mb4 in the third control module 170 is NMOS, then the first control terminal A is the third node N3, and the signal of the third node N3 controls the first control module 130 and the third control module 170 to be turned on in a time-sharing manner. When the signal of the third node N3 is at high level, the first transistor Mb1 is controlled to be turned off and the fourth transistor Mb4 is controlled to be turned on, and the fifth power supply signal vgh3 is written to the fourth node N4, so that it is ensured that the fourth node N4 is at high level, and the leakage current of the fourth node N4 to the first node N1 can be reduced. When the signal of the third node N3 is at low level, the first transistor Mb1 is controlled to be turned on and the fourth transistor Mb4 is controlled to be turned off, and the signal of the first node N1 is written to the fourth node N4. Reference can be made to FIG. 9 for the low-frequency operation timing of the shift register 12 in FIG. 15, and reference can be made to FIG. 10 for the high-frequency operation timing of the shift register 12 in FIG. 15, and the description will not be repeated here.

For the above-mentioned embodiments, the shift register 12 includes a first control module 130 and a second control module 140. On this basis, the arrangements of the third control module 170, the fourth control module 160, the first coupling module 181, the second coupling module 182, and the third coupling module 183 are all optional for the shift register 12. That is, the shift register 12 may not include the third control module 170, the fourth control module 160, the first coupling module 181, the second coupling module 182 or the third coupling module 183, or the shift register 12 may include at least one of the third control module 170, the fourth control module 160, the first coupling module 181, the second coupling module 182 and the third coupling module 183. Under the premise of ensuring the normal operation of the shift register 12, relevant practitioners can reasonably design the specific components and structures of the shift register 12 according to the product requirements, which are not limited to the above illustrations.

The inventors have found through research that the scan output portion 14 of the shift register 12 is not limited to the above structures, and the scan output portion 14 may not include the second control module 140, and by reasonably designing the structure of the scan output portion 14 in the shift register 12, it is ensured that the shift register 12 operates normally and the output is stable and effective. The following embodiments provide different multiple scan output portions 14, wherein the scan output portion 14 may include the second control module 140 or not include the second control module 140.

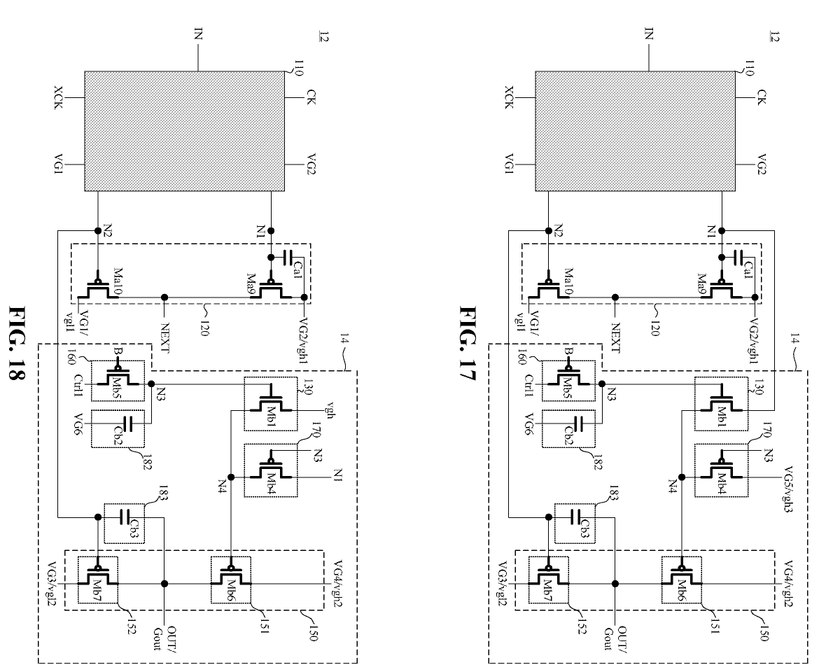

FIG. 16 is a schematic diagram of a shift register according to even still yet another embodiment of the present application, and as shown in FIG. 16, optionally, the scan output portion 14 of the shift register 12 does not include the second control module. Optionally, the scan output portion 14 is in a 5T3C structure, in which "5T" of the scan output portion 14 includes a first transistor Mb1, a fourth transistor Mb4, a fifth transistor Mb5, a sixth transistor Mb6, and a seventh transistor Mb7, and "3C" of the scan output portion 14 includes a first capacitor Cb1, a second capacitor Cb2, and a third capacitor Cb3. Optionally, the five transistors in the scan output portion 14 are all PMOS, which is not limited thereto. Reference can be made to FIG. 9 for the low-frequency operation timing of the shift register 12, and reference can be made to FIG. 10 for the high-frequency operation timing of the shift register 12, which are not repeated in the present application.

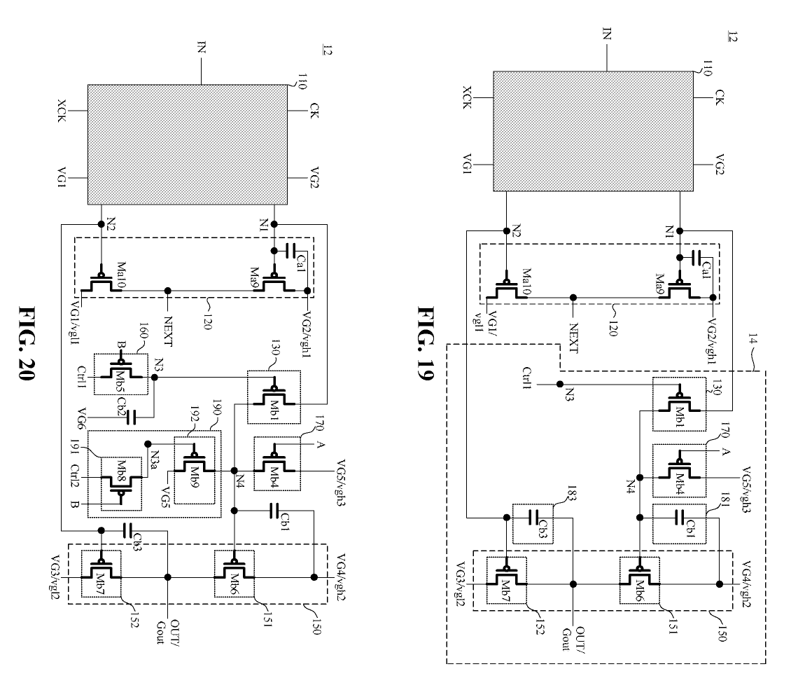

FIG. 17 is a schematic diagram of a shift register according to even still yet another embodiment of the present application, FIG. 17 is different from FIG. 16. Specifically, the scan output portion 14 in FIG. 17 is in a 5T2C structure, in which the first transistor Mb1 is NMOS, the fourth transistor Mb4 is PMOS, the gate of the fourth transistor Mb4 is electrically connected to the third node N3, and the scan output portion 14 may include only two capacitors including the second capacitor Cb2 and the third capacitor Cb3.

FIG. 18 is a schematic diagram of a shift register according to even still yet another embodiment of the present application, FIG. 18 is different from FIG. 16. Specifically, the scan output portion 14 in FIG. 18 is in a 5T2C structure, in which the first transistor Mb1 is NMOS and the fourth transistor Mb4 is PMOS, the first terminal of the first transistor Mb1 receives a high level and the second terminal of the first transistor Mb1 is electrically connected to the fourth node N4, the high level received by the first terminal of the first transistor Mb1 may come from the second power supply terminal VG2, the fourth power supply terminal VG4, or the fifth power supply terminal VG5, the gate of the fourth transistor Mb4 is electrically connected to the third node N3, the first terminal of the fourth transistor Mb4 is electrically connected to the first node N1 and the second terminal of the fourth transistor Mb4 is electrically connected to the fourth node N4, and the scan output portion 14 may include only two capacitors including the second capacitor Cb2 and the third capacitor Cb3.

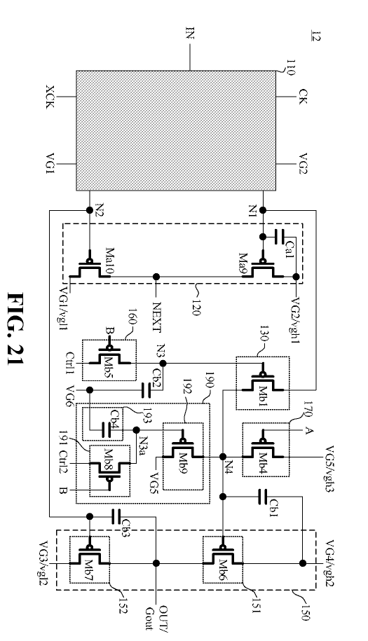

FIG. 19 is a schematic diagram of a shift register according to even still yet another embodiment of the present application, FIG. 19 is different from FIG. 16. Specifically, the scan output portion 14 in FIG. 19 is in a 4T2C structure, in which the third node N3 of the shift register 12 may be directly electrically connected to the first refresh signal line SCL1 to receive the first refresh control signal Ctrl1, and the scan output portion 14 may include only two capacitors including the first capacitor Cb1 and the third capacitor Cb3.

With reference to FIGS. 9 and 10, for the shift register 12 shown in FIG. 19, when the first refresh control signal Ctrl1 received by the third node N3 thereof is at high level, the first transistor Mb1 is turned off, and the shift register 12 is in a low-refresh rate mode. On the contrary, when the first refresh control signal Ctrl1 received by the third node N3 of the shift register 12 is at low level, the first transistor Mb1 is turned on, and the electrical signal of the first node N1 is written to the fourth node N4, the shift register 12 is in a high-refresh rate mode. Therefore, the position for toggling between high and low levels of the first refresh control signal Ctrl1 is the boundary between the low-refresh rate display area and the high-refresh rate display area.

In this embodiment, a plurality of refresh signal lines may be adopted, and each refresh signal line is electrically connected to a continuous multi-stage shift register, so that the toggling of the refresh control signal of each refresh signal line does not affect the output validity of the shift register 12.

In the above-mentioned embodiments, on the premise of ensuring the normal operation of the shift register 12, the structure of the scan output portion 14 may be adjusted, and the structure of the scan output portion 14 may be "5T3C", "5T2C", "4T2C", or others, and relevant practitioners can reasonably design the specific components and structures of the shift register 12 according to the product requirements, which are not limited to the above illustrations.

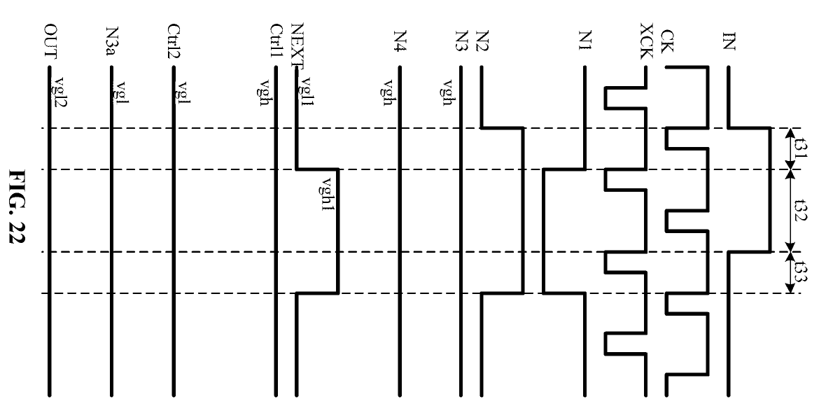

FIG. 20 is a schematic diagram of a shift register according to even still yet another embodiment of the present application, and FIG. 21 is a schematic diagram of a shift register according to even still yet another embodiment of the present application. The difference from any of the above embodiments is that the shift register 12 in FIG. 20 and FIG. 21 is electrically connected to two refresh signal lines.

As shown in FIGS. 20 and 21, optionally, the shift register 12 further includes: a fifth control module 190. The fifth control module 190 is electrically connected to the second control terminal B, the second refresh signal line, the fifth power supply terminal VG5, and the fourth node N4 for controlling the signal of the fourth node N4. The second control terminal B is one of the fifth node N5, the second node N2, and the shift output terminal NEXT.

In the present embodiment, the display panel includes a second refresh signal line and a first refresh signal line, the first refresh signal line provides a first refresh control signal Ctrl1 to the shift register 12, and the second refresh signal line provides a second refresh control signal Ctrl2 to the shift register 12. The first refresh control signal Ctrl1 provided by the first refresh signal line can be transmitted to the third node N3 through the fourth control module 160; in other embodiments, optionally, the first refresh control signal Ctrl1 provided by the first refresh signal line can be directly transmitted to the third node N3.

Referring to FIGS. 7, 20, and 21, it can be understood that the second control terminal B may be the fifth node N5, the node N5a, the second node N2, the node N2b, or the shift output terminal NEXT.

Optionally, the fifth control module 190 includes: a first control sub-module 191 electrically connected to the second control terminal B, the second refresh signal line, and the first sub-node N3a, and configured to control a signal of the first sub-node N3a; and a second control sub-module 192 electrically connected to the first sub-node N3a, the fifth power supply terminal VG5, and the fourth node N4 and configured to control the signal of the fourth node N4. Optionally, the first control sub-module 191 includes an eighth transistor Mb8. The gate of the eighth transistor Mb8 is electrically connected to the second control terminal B, the first terminal of the eighth transistor Mb8 is electrically connected to the second refresh signal line, and the second terminal of the eighth transistor Mb8 is electrically connected to the first sub-node N3a. The second control sub-module 192 includes a ninth transistor Mb9. The gate of the ninth transistor Mb9 is electrically connected to the first sub-node N3a, the first terminal of the ninth transistor Mb9 is electrically connected to the fifth power supply terminal VG5, and the second terminal of the ninth transistor Mb9 is electrically connected to the fourth node N4.

In the present embodiment, the first terminal of the eighth transistor Mb8 in the first control sub-module 191 receives the second refresh control signal Ctrl2 provided by the second refresh signal line. The signal of the second control terminal B controls the on-off state of the first control sub-module 191. Specifically, when the signal of the second control terminal B controls the eighth transistor Mb8 to be turned on, the second refresh control signal Ctrl2 is transmitted to the first sub-node N3a. When the signal from the second control terminal B controls the eighth transistor Mb8 to be turned off, the first sub-node N3a remains at the level of the previous stage.

The gate of the ninth transistor Mb9 in the second control sub-module 192 is electrically connected to the first sub-node N3a. The signal of the first sub-node N3a controls the on-off state of the second control sub-module 192. Specifically, when the signal of the first sub-node N3a controls the ninth transistor Mb9 to be turned on, the fifth power supply signal provided by the fifth power supply terminal VG5 is transmitted to the fourth node N4. When the signal of the first sub-node N3a controls the ninth transistor Mb9 to be turned off, the fourth node N4 remains at the level of the previous stage or is adjusted by the influence of other nodes.

As shown in FIG. 21, optionally, the fifth control module 190 further includes: a coupling sub-module 193, a first terminal of the coupling sub-module 193 is electrically connected to the sixth power supply terminal VG6, and a second terminal of the coupling sub-module 193 is electrically connected to the first sub-node N3a. Optionally, the coupling sub-module 193 includes a fourth capacitor Cb4. The first plate of the fourth capacitor Cb4 is electrically connected to the sixth power supply terminal VG6, and the second plate of the fourth capacitor Cb4 is electrically connected to the first sub-node N3a.

Optionally, the control signal Ctrl2 provided by the second refresh signal line is different from the control signal Ctrl1 provided by the first refresh signal line. Optionally, the control signal Ctrl2 provided by the second refresh signal line and the control signal Ctrl1 provided by the first refresh signal line are both signals toggling between high and low levels, and have opposite phases.

In this embodiment, the operation principle of the shift register 12 is described by taking an example where the active level of the first refresh control signal Ctrl1 is the low level vgl and the inactive level of the first refresh control signal Ctrl1 is the high level vgh. Accordingly, when the first refresh control signal Ctrl1 provided by the first refresh signal line is at low level vgl, the second refresh control signal Ctrl2 provided by the second refresh signal line is at high level vgh; On the contrary, when the first refresh control signal Ctrl1 is at the high level vgh, the second refresh control signal Ctrl2 is at the low level vgl. Optionally, the first control terminal A is electrically connected to the second node N2, and the second control terminal B is electrically connected to the shift output terminal NEXT.

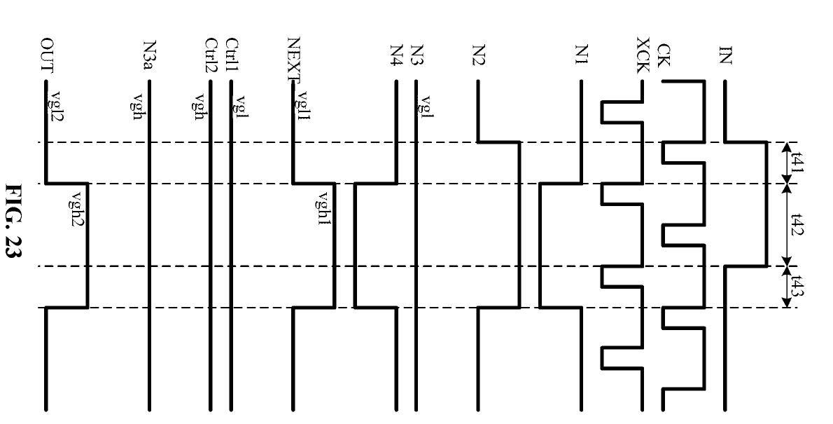

Taking FIG. 21 as an example, FIG. 22 is a low-frequency operation timing diagram of the shift register 12 in the first display partition shown in FIG. 21. Referring to FIGS. 21 and 22, in the first display partition, the shift signal frequency of the shift register 12 is greater than the gate driving signal frequency. Therefore, when the shift register 12 operates at a low frequency, there is a situation where the shift signal is at an active level while the gate driving signal is at an inactive level, thereby achieving low-frequency operation.

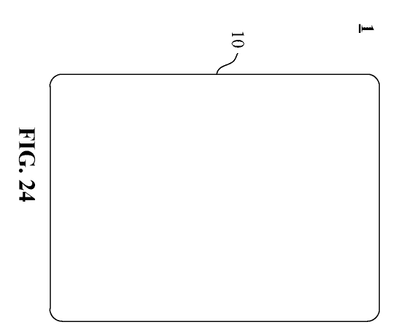

FIG. 23 is a high-frequency operation timing diagram of the shift register 12 in the second display partition shown in FIG. 21. Referring to FIGS. 21 and 23, optionally, in the second display partition, the shift signal frequency of the shift register 12 is equal to the gate driving signal frequency. Therefore, when the shift register 12 operates at a high frequency, there is a situation where the shift signal is at an active level while the gate driving signal is at an active level, thereby achieving high-frequency operation.

Referring to FIGS. 21 and 22, the low-frequency operation process of the shift register 12 includes the following the stages.

In the phase t31, the second node N2 is at the high level, the first node N1 remains at at the high level of the previous stage, and the shift signal of the shift output terminal NEXT remains at the low level vgl1 of the previous stage, that is, the inactive level; both the transistor Mb5 and the transistor Mb8 are turned on, the third node N3 is at the high level vgh of the first refresh control signal Ctrl1, the transistor Mb1 is turned off, the first sub-node N3a is at the low level vgl of the second refresh control signal Ctrl2, and the transistor Mb9 is turned on; the fifth power supply signal vgh3 of the fifth power supply terminal VG5 is written to the fourth node N4, and the fourth node N4 is at high level; the transistor Mb6 is turned off and the transistor Mb7 is turned off, and the gate driving signal Gout of the scan output terminal OUT is remained at the low level vgl2.

The stages t32 to t33 are also the active level output stages of the shift signal of the shift register 12, the second node N2 is at the high level, the first node N1 is at the low level, the second power supply signal vgh1 provided by the second power supply terminal VG2 is transmitted to the shift output terminal NEXT, and the shift signal is at the high level vgh1, that is, the active level; both the transistor Mb5 and the transistor Mb8 are turned off, the third node N3 remains at the high level vgh of the previous stage, and the fourth node N4 remains at the high level vgh3 of the previous stage; the transistor Mb6 is turned off and the transistor Mb7 is turned off, and the gate driving signal Gout of the scan output terminal OUT remains at low level vgl2, that is, an inactive level. It can be seen that in this stage, the shift signal is the active level and the gate driving signal Gout is at the inactive level.

After the phase t33, the second node N2 is at low level, the first node N1 is at high level vgh1, and the shift signal of the shift output terminal NEXT is at low level vgl1; both the transistor Mb5 and the transistor Mb8 are turned on, the third node N3 is at the high level vgh, the first sub-node N3a is at the low level vgl, so that the transistor Mb9 is turned on, the fifth power supply signal vgh3 is written to the fourth node N4, the transistor Mb6 is turned off and the transistor Mb7 is turned on, and the gate driving signal Gout of the scan output terminal OUT is at the low level vgl2.

Referring to FIGS. 21 and 23, the high-frequency operation process of the shift register 12 includes the following stages.

In the phase t41, when the second node N2 is at the high level and the first node N1 remains at the high level of the previous stage, the shift signal of the shift output terminal NEXT remains at the low level vgl1 of the previous stage, that is, the inactive level; both the transistor Mb5 and the transistor Mb8 are turned on, the third node N3 is at the low level vgl of the first refresh control signal Ctrl1, the transistor Mb1 is turned on, the first sub-node N3a is at the high level vgh of the second refresh control signal Ctrl2, and the transistor Mb9 is turned off; the high level of the first node N1 is written to the fourth node N4, and the fourth node N4 is at the high level; the transistor Mb6 is turned off and the transistor Mb7 is turned off, and the gate driving signal Gout of the scan output terminal OUT remains at the low level vgl2.

In the phase t42 to t43, the second node N2 is at the high level, the first node N1 is at the low level, the second power supply signal vgh1 is transmitted to the shift output terminal NEXT, and the shift signal is at the high level vgh1, that is, the active level; both the transistor Mb5 and the transistor Mb8 are turned off, the third node N3 remains at the low level vgl of the previous stage, the transistor Mb1 is turned on, and the low level vgl of the first node N1 is written to the fourth node N4; the first sub-node N3a remains at the high level vgh of the previous stage, and the transistor Mb9 is turned off; the transistor Mb6 is turned on and the transistor Mb7 is turned off, the fourth power supply signal vgh2 is written to the scan output terminal OUT, and the gate driving signal Gout is at high level vgh2, that is, an active level. It can be seen that in this stage, the shift signal is at the active level and the gate driving signal Gout is at the active level.

After the phase t43, the second node N2 is at the low level, the first node N1 is at the high level vgh1, the first power supply signal vgl1 is transmitted to the shift output terminal NEXT, and the shift signal is at the low level vgl1, that is, the inactive level; Both the transistor Mb5 and the transistor Mb8 are turned on, the third node N3 is at the low level vgl of the first refresh control signal Ctrl1, the transistor Mb1 is turned on, the first sub-node N3a is at the high level vgh of the second refresh control signal Ctrl2, and the transistor Mb9 is turned off; the high level of the first node N1 is written to the fourth node N4; the transistor Mb6 is turned off and the transistor Mb7 is turned on, the third power supply signal vgl2 is written to the scan output terminal OUT, and the gate driving signal Gout is at low level vgl2.

As described above, when the shift register 12 operates in the low-frequency mode or the high-frequency mode, the potential of the fourth node N4 is stable, and the fourth node N4 does not erroneously trigger the sixth transistor Mb6, thereby ensuring the circuit stability and validity of the shift register 12. Based on the shift register structure, the display panel can realize partition refresh at any position, which can save power consumption and improve the output stability and validity of partition refresh, especially the output validity of low-refresh display area.

It should be noted that the structures of the shift registers in the embodiments of the present application are not limited thereto, and shift registers having structures such as increasing or decreasing the corresponding transistors on this basis are applicable to the embodiments of the present application, and the embodiments of the present application will not give examples thereof one by one. Exemplarily, the transistor Mb4 may be deleted in another shift register on the basis of FIG. 20, and its operation process is similar to that of other shift registers, which is not described in detail. Apparently, the structure of the shift register in the embodiments of the present application may be various, and is not limited thereto.

Based on the same inventive concept, an embodiment of the present application further provides a display apparatus including the display panel provided by the embodiments of the present application. Therefore, the display apparatus has the technical characteristics of the display panel provided by the embodiments of the present application and the driving process thereof, and can achieve the beneficial effects of the display panel provided by the embodiments of the present application. For similarities, the above description of the display panel provided by the embodiments of the present application can be referred to, which is not repeated here.

Exemplarily, FIG. 24 is a schematic structural diagram of a display apparatus according to an embodiment of the present application, and as shown in FIG. 24, the display apparatus 1 includes a display panel 10 according to an embodiment of the present application. The display apparatus 1 provided by the embodiments of the present application may be any electronic product having a display function, including but not limited to the following categories: mobile phones, televisions, notebook computers, desktop displays, tablet computers, digital cameras, smart bracelets, smart glasses, vehicle displays, medical devices, industrial control devices, touch interactive terminals, and the like, and the embodiments of the present application are not particularly limited thereto.

It should be understood that steps may be reordered, added, or deleted using the various forms of processes shown above. For example, the steps described in the present application may be executed in parallel, sequentially, or in different orders, and are not limited herein as long as the desired results of the aspect of the present application can be achieved.

The above-mentioned specific embodiments do not limit the scope of protection of the present application. It should be understood by those skilled in the art that various modifications, combinations, sub-combinations, and substitutions may be made depending on design requirements and other factors. Any modification, equivalent substitution and improvement made within the gist and principles of the present application should be included within the protection scope of the present application.

What is claimed is:

1. A display panel, comprising: a first driving circuit, the first driving circuit comprising a plurality of stages of shift registers, each of the shift registers comprising:
a shift control module, electrically connected to an input terminal, a first clock terminal, a second clock terminal, a first power supply terminal, a second power supply terminal, a first node, and a second node and configured to control a signal of the first node and a signal of the second node;
a shift output module, electrically connected to the first node, the second node, the first power supply terminal, the second power supply terminal, and a shift output terminal and configured to control the shift output terminal to output a shift signal;
a first control module, electrically connected to the first node, a third node, and a fourth node and configured to control a signal of the fourth node, the third node being configured to receive a first refresh control signal provided by a first refresh signal line;
a second control module, electrically connected to the third node and the fourth node and configured to adjust the signal of the fourth node, the second control module being further electrically connected to the first node, and/or the first control module being electrically connected to the fourth node through the second control module; and
a refresh output module, electrically connected to the second node, the fourth node, a third power supply terminal, a fourth power supply terminal, and a scan output terminal and configured to control the scan output terminal to output a gate driving signal.

2. The display panel according to claim 1, wherein the first control module comprises: a first transistor, a gate of the first transistor being electrically connected to the third node, a first terminal of the first transistor being electrically connected to the first node, and a second terminal of the first transistor being electrically connected to the fourth node.

3. The display panel according to claim 1, wherein the second control module comprises: a second transistor, a gate of the second transistor being electrically connected to the first node, a first terminal of the second transistor being electrically connected to the third node, and a second terminal of the second transistor being electrically connected to the fourth node.

4. The display panel according to claim 1, wherein the second control module comprises: a third transistor, a gate of the third transistor being electrically connected to the third node, a first terminal of the third transistor being electrically connected to the first control module, and a second terminal of the third transistor being electrically connected to the fourth node.

5. The display panel according to claim 1, wherein the shift control module comprises:
a first shift sub-module, electrically connected to the input terminal, the first clock terminal, and a fifth node and configured to control a signal of the fifth node;
a second shift sub-module, electrically connected to the fifth node, the first clock terminal, the second clock terminal, the first power supply terminal, the second power supply terminal, and the first node and configured to control the signal of the first node; and
a third shift sub-module, electrically connected to the fifth node, the second clock terminal, the first power supply terminal, the second power supply terminal, and the second node and configured to control the signal of the second node.

6. The display panel according to claim 5, wherein the shift register further comprises: a third control module, electrically connected to a fifth power supply terminal, a first control terminal, and the fourth node and configured to control the signal of the fourth node; and
wherein the first control terminal is one of the fifth node, the second node, the shift output terminal, and the third node, wherein the third control module comprises: a fourth transistor, a gate of the fourth transistor being electrically connected to the first control terminal, a first terminal of the fourth transistor being electrically connected to the fifth power supply terminal, and a second terminal of the fourth transistor being electrically connected to the fourth node.

7. The display panel according to claim 6, wherein a level signal provided by the fifth power supply terminal is different from a level signal provided by the fourth power supply terminal.

8. The display panel according to claim 6, wherein a level signal provided by the fifth power supply terminal is greater than or equal to a level signal provided by the fourth power supply terminal.

9. The display panel according to claim 6, wherein at least two of a level signal provided by the second power supply terminal, a level signal provided by the fourth power supply terminal, and a level signal provided by the fifth power supply terminal are a same signal.

10. The display panel according to claim 6, wherein the first control terminal is the third node; and
a signal of the third node controls the first control module and the third control module to be turned on in a time-sharing manner.

11. The display panel according to claim 6, wherein the shift register further comprises a first coupling module, a first terminal of the first coupling module being electrically connected to one of the second power supply terminal, the fourth power supply terminal, and the fifth power supply terminal, and a second terminal of the first coupling module being electrically connected to the fourth node, wherein the first coupling module comprises a first capacitor, a first plate of the first capacitor being a first terminal of the first coupling module, and a second plate of the first capacitor being electrically connected to the fourth node.

12. The display panel according to claim 5, wherein the shift register further comprises a fourth control module;
the fourth control module is electrically connected to a second control terminal;
the first refresh signal line provides the first refresh control signal to the third node through the fourth control module; and
the second control terminal is one of the fifth node, the second node, and the shift output terminal, wherein the fourth control module comprises: a fifth transistor, a gate of the fifth transistor being electrically connected to the second control terminal, a first terminal of the fifth transistor being electrically connected to the first refresh signal line, and a second terminal of the fifth transistor being electrically connected to the third node, wherein the fifth transistor is a double-gate transistor.

13. The display panel according to claim 1, wherein the shift register further comprises: a second coupling module, a first terminal of the second coupling module being electrically connected to a sixth power supply terminal, and a second terminal of the second coupling module being electrically connected to the third node, wherein the second coupling module comprises: a second capacitor, a first plate of the second capacitor being electrically connected to the sixth power supply terminal, and a second plate of the second capacitor being electrically connected to the third node.

14. The display panel according to claim 13, wherein at least two of a level signal provided by the first power supply terminal, a level signal provided by the third power supply terminal, and a level signal provided by the sixth power supply terminal are a same signal.

15. The display panel according to claim 13, wherein a level signal provided by the sixth power supply terminal and a level signal provided by the second power supply terminal are a same signal; or, the level signal provided by the sixth power supply terminal and a level signal provided by the fourth power supply terminal are the same signal.

16. The display panel according to claim 1, wherein the refresh output module comprises:
a first output sub-module, electrically connected to the fourth node, the fourth power supply terminal, and the scan output terminal and configured to control the scan output terminal to output the gate driving signal; and
a second output sub-module, electrically connected to the second node, the third power supply terminal, and the scan output terminal and configured to control the scan output terminal to output the gate driving signal, wherein the first output sub-module comprises a sixth transistor, a gate of the sixth transistor being electrically connected to the fourth node, a first terminal of the sixth transistor being electrically connected to the fourth power supply terminal, and a second terminal of the sixth transistor being electrically connected to the scan output terminal, or,
wherein the second output sub-module comprises a seventh transistor, a gate of the seventh transistor being electrically connected to the second node, a first terminal of the seventh transistor being electrically connected to the third power supply terminal, and a second terminal of the seventh transistor being electrically connected to the scan output terminal.

17. The display panel according to claim 1, wherein a level signal provided by the first power supply terminal is different from a level signal provided by the third power supply terminal.

18. The display panel according to claim 1, wherein a level signal provided by the first power supply terminal is less than or equal to a level signal provided by the third power supply terminal.

19. The display panel according to claim 1, wherein the shift register further comprises: a third coupling module, a first terminal of the third coupling module being electrically connected to the scan output terminal, and a second terminal of the third coupling module being electrically connected to the second node, wherein the third coupling module comprises: a third capacitor, a first plate of the third capacitor being electrically connected to the scan output terminal, and a second plate of the third capacitor being electrically connected to the second node.

20. The display panel according to claim 5, wherein the shift register further comprises:
a fifth control module;
the fifth control module is electrically connected to a second control terminal, a second refresh signal line, a fifth power supply terminal, and the fourth node and is configured to control the signal of the fourth node; and
the second control terminal is one of the fifth node, the second node, and the shift output terminal, wherein the fifth control module comprises:
a first control sub-module, electrically connected to the second control terminal, the second refresh signal line, and a first sub-node and configured to control a signal of the first sub-node; and
a second control sub-module, electrically connected to the first sub-node, the fifth power supply terminal, and the fourth node and configured to control the signal of the fourth node, wherein the first control sub-module comprises: an eighth transistor, a gate of the eighth transistor being electrically connected to the second control terminal, a first terminal of the eighth transistor being electrically connected to the second refresh signal line, and a second terminal of the eighth transistor being electrically connected to the first sub-node; and
the second control sub-module comprises a ninth transistor, a gate of the ninth transistor being electrically connected to the first sub-node, a first terminal of the ninth transistor being electrically connected to the fifth power supply terminal, and a second terminal of the ninth transistor being electrically connected to the fourth node.

21. The display panel according to claim 20, wherein the fifth control module further comprises:
a coupling sub-module, a first terminal of the coupling sub-module being electrically connected to a sixth power supply terminal, and a second terminal of the coupling sub-module being electrically connected to the first sub-node, wherein the coupling sub-module comprises: a fourth capacitor, a first plate of the fourth capacitor being electrically connected to the sixth power supply terminal, and a second plate of the fourth capacitor being electrically connected to the first sub-node.

22. The display panel according to claim 20, wherein a control signal provided by the second refresh signal line is different from a control signal provided by the first refresh signal line.

23. The display panel according to claim 20, wherein a control signal provided by the second refresh signal line and a control signal provided by the first refresh signal line are both signals toggling between high and low levels and have opposite phases.

24. The display panel according to claim 1, wherein the display panel has a multi-frequency refresh mode; and
in the multi-frequency refresh mode, a display area of the display panel comprises a first display partition and a second display partition, a refresh frequency of the first display partition is a first refresh frequency, a refresh frequency of the second display partition is a second refresh frequency, and the first refresh frequency is less than the second refresh frequency.

25. The display panel according to claim 24, wherein in the multi-frequency refresh mode, a frequency of the shift signal of the shift register in the first display partition is greater than a frequency of the gate driving signal; and
in the multi-frequency refresh mode, the frequency of the gate driving signal of the shift register in the first display partition is less than the frequency of the gate driving signal of the shift register in the second display partition.

26. A display apparatus, comprising a display panel comprising:
a first driving circuit, the first driving circuit comprising a plurality of stages of shift registers, each of the shift registers comprising: a shift control module, electrically connected to an input terminal, a first clock terminal, a second clock terminal, a first power supply terminal, a second power supply terminal, a first node, and a second node and configured to control a signal of the first node and a signal of the second node; a shift output module, electrically connected to the first node, the second node, the first power supply terminal, the second power supply terminal, and a shift output terminal and configured to control the shift output terminal to output a shift signal; a first control module, electrically connected to the first node, a third node, and a fourth node and configured to control a signal of the fourth node, the third node being configured to receive a first refresh control signal provided by a first refresh signal line; a second control module, electrically connected to the third node and the fourth node and configured to adjust the signal of the fourth node, the second control module being further electrically connected to the first node, or the first control module being electrically connected to the fourth node through the second control module; and a refresh output module, electrically connected to the second node, the fourth node, a third power supply terminal, a fourth power supply terminal, and a scan output terminal and configured to control the scan output terminal to output a gate driving signal.
